(19) United States
(12) Patent Application Publication
(10) Pub. No.: US 2025/0338752 A1
(43) Pub. Date: Oct. 30, 2025

(54) DISPLAY DEVICE INCLUDING AUXILIARY ELECTRODES, METHOD OF MANUFACTURING THE SAME, AND AN ELECTRONIC DEVICE INCLUDING THE DISPLAY DEVICE

(71) Applicant: SAMSUNG DISPLAY CO., LTD., YONGIN-SI (KR)

(72) Inventor: HYUNEOK SHIN, Yongin-si (KR)

(21) Appl. No.: 19/008,911

(22) Filed: Mar. 12, 2025

(30) Foreign Application Priority Data
Apr. 25, 2024 (KR) 10-2024-0055447

(51) Int. Cl. H10K 59/80; H10K 59/12; H10K 71/20; H10K 71/60

(52) U.S. Cl. CPC H10K 59/80522; H10K 59/1201; H10K 71/231; H10K 71/60

(57) ABSTRACT

A display device includes: a first pixel electrode disposed on a substrate; a first organic functional layer disposed on the first pixel electrode; a first auxiliary electrode disposed on the first organic functional layer, and overlapping a first side of the first organic functional layer; and a common electrode disposed on the first auxiliary electrode and covering the first organic functional layer and the first auxiliary electrode.

### CROSS-REFERENCE TO RELATED APPLICATION

This application claims priority under 35 U.S.C. § 119 to Korean Patent Application No. 10-2024-0055447, filed on Apr. 25, 2024, the disclosure of which is incorporated by reference herein in its entirety.

### TECHNICAL FIELD

Embodiments of the present invention relate generally to a display device, a method of manufacturing the display device, and an electronic device including the display device, and more particularly, to a display device including auxiliary electrodes and a method of manufacturing the display device.

### DISCUSSION OF THE RELATED ART

Generally, a display device is a device that displays an image, and examples of the display device include an organic light emitting display device and a liquid crystal display device. Generally, an organic light emitting display device includes an organic emission layer that is interposed between a pixel electrode and a common electrode. When the two electrodes respectively inject electrons and holes into the organic emission layer, light is emitted according to the combination of electrons and holes.

### SUMMARY

According to an embodiment of the present invention, a display device includes: a first pixel electrode disposed on a substrate; a first organic functional layer disposed on the first pixel electrode; a first auxiliary electrode disposed on the first organic functional layer, and overlapping a first side of the first organic functional layer; and a common electrode disposed on the first auxiliary electrode and covering the first organic functional layer and the first auxiliary electrode.

In an embodiment of the present invention, a boundary of the first auxiliary electrode is aligned with a boundary of the first organic functional layer.

In an embodiment of the present invention, the first auxiliary electrode does not overlap a central portion of the first organic functional layer.

In an embodiment of the present invention, the first auxiliary electrode contacts the common electrode.

In an embodiment of the present invention, the first auxiliary electrode is interposed between the first organic functional layer and the common electrode.

In an embodiment of the present invention, the first auxiliary electrode includes a same material as the common electrode.

In an embodiment of the present invention, the first auxiliary electrode includes a material that is different from a material of the common electrode.

In an embodiment of the present invention, the display device further includes: an inorganic capping layer disposed on the first organic functional layer and spaced apart from the first auxiliary electrode.

In an embodiment of the present invention, the display device further includes: a spacer disposed on the inorganic capping layer and spaced apart from the first auxiliary electrode.

In an embodiment of the present invention, the first auxiliary electrode includes: a 1-1 auxiliary electrode overlapping the first side of the first organic functional layer; and a 1-2 auxiliary electrode overlapping a second side that is opposite to the first side of the first organic functional layer.

In an embodiment of the present invention, the display device further includes: a second pixel electrode disposed on the substrate and spaced apart from the first pixel electrode; a second organic functional layer disposed on the second pixel electrode; a 2-1 auxiliary electrode disposed on the second organic functional layer, and overlapping a first side of the second organic functional layer; and a 2-2 auxiliary electrode disposed on the second organic functional layer, and overlapping a second side opposite to the first side of the second organic functional layer.

In an embodiment of the present invention, the first auxiliary electrode does not overlap a second side that is opposite to the first side of the first organic functional layer.

In an embodiment of the present invention, the display device further includes: a second pixel electrode disposed on the substrate and spaced apart from the first pixel electrode; a second organic functional layer disposed on the second pixel electrode; and a second auxiliary electrode disposed on the second organic functional layer, and overlapping a first side of the second organic functional layer, wherein the second auxiliary electrode does not overlap a second side that is opposite to the first side of the second organic functional layer.

In an embodiment of the present invention, the display device further includes: a second pixel electrode disposed on the substrate and spaced apart from the first pixel electrode; and a second organic functional layer disposed on the second pixel electrode, wherein the common electrode covers a whole surface of the second organic functional layer.

According to an embodiment of the present invention, a method of manufacturing a display device includes: forming a first pixel electrode on a substrate; forming a first organic functional layer on the first pixel electrode; forming a preliminary first auxiliary electrode layer on the first organic functional layer, wherein the preliminary first auxiliary electrode layer contacts the first organic functional layer; forming a first auxiliary electrode by patterning the preliminary first auxiliary electrode layer, wherein the first auxiliary electrode overlaps a first side of the first organic functional layer; and forming a common electrode on the first auxiliary electrode, wherein the common electrode covers the first organic functional layer and the first auxiliary electrode.

In an embodiment of the present invention, the method further includes: forming a preliminary inorganic capping layer on the preliminary first auxiliary electrode layer; removing a portion of the preliminary inorganic capping layer that overlaps a central portion of the first organic functional layer, through a first etching process; and forming a first auxiliary electrode layer by removing a portion of the preliminary first auxiliary electrode layer that overlaps the central portion of the first organic functional layer, through the first etching process.

In an embodiment of the present invention, the method further includes: removing a portion of the preliminary inorganic capping layer that overlaps the first side of the first organic functional layer, through a second etching process; and forming a preliminary first auxiliary electrode by removing a portion of the first auxiliary electrode layer that overlaps the central portion of the first organic functional layer, through the second etching process.

In an embodiment of the present invention, the first auxiliary electrode is formed by removing a portion of the preliminary first auxiliary electrode that overlaps the central portion of the first organic functional layer, through a third etching process.

In an embodiment of the present invention, the method further includes: forming a second pixel electrode on the substrate, wherein the second pixel electrode is spaced apart from the first pixel electrode; depositing a first organic functional material layer covering the first pixel electrode and the second pixel electrode; depositing a first auxiliary electrode material layer on the first organic functional material layer; and forming the first organic functional layer and the preliminary first auxiliary electrode layer together, by patterning the first organic functional material layer and the first auxiliary electrode material layer.

In an embodiment of the present invention, the method further includes: depositing a second organic functional material layer on the first organic functional layer and the preliminary first auxiliary electrode layer; depositing a second auxiliary electrode material layer on the second organic functional material layer; and forming a second organic functional layer and a preliminary second auxiliary electrode layer together, by patterning the second organic functional material layer and the second auxiliary electrode material layer.

According to an embodiment of the present invention, an electronic device includes a display device and a power supply configured to provide power to the display device. The display device includes: a first pixel electrode disposed on a substrate; a first organic functional layer disposed on the first pixel electrode; a first auxiliary electrode disposed on the first organic functional layer, and overlapping a first side of the first organic functional layer; and a common electrode disposed on the first auxiliary electrode and covering the first organic functional layer and the first auxiliary electrode.

### BRIEF DESCRIPTION OF THE DRAWINGS

The above and other features of the present invention will become more apparent by describing in detail embodiments thereof, with reference to the accompanying drawings, in which:

FIG. 1 is a plan view illustrating a display device according to an embodiment of the present invention.

FIG. 2 is a cross-sectional view illustrating the display device of FIG. 1.

FIG. 3 is a cross-sectional view illustrating a transistor layer included in the display device of FIG. 2.

FIG. 4 is a cross-sectional view illustrating a thin film encapsulation layer, a color conversion layer, and a glass encapsulation layer included in the display device of FIG. 2.

FIG. 5 is a cross-sectional view illustrating an emission layer included in the display device of FIG. 2.

FIGS. 6, 7, 8, 9, 10, 11, 12, 13, 14, 15, 16, 17, 18, 19, 20, 21, 22, 23, 24, 25, 26, 27, 28, 29, 30, 31, and 32 are cross-sectional views illustrating a method of manufacturing the emission layer of FIG. 5.

FIG. 33 is a plan view illustrating a display device according to an embodiment of the present invention.

FIG. 34 is a cross-sectional view illustrating an emission layer included in the display device of FIG. 33.

FIG. 35 is a plan view illustrating a display device according to an embodiment of the present invention.

FIG. 36 is a cross-sectional view illustrating an emission layer included in the display device of FIG. 35.

FIG. 37 is a block diagram illustrating an electronic device according to an embodiment of the present invention.

### DETAILED DESCRIPTION OF THE EMBODIMENTS

Illustrative, non-limiting embodiments will be more clearly understood from the following detailed description in conjunction with the accompanying drawings.

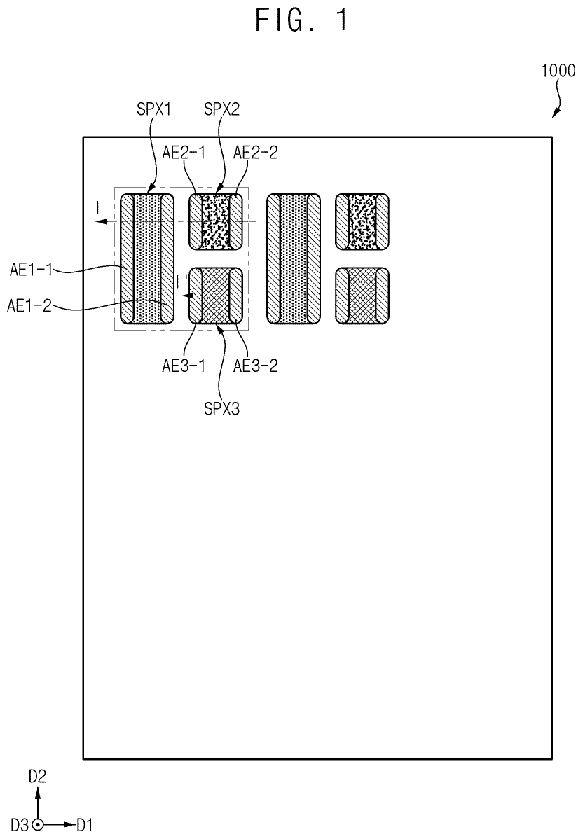

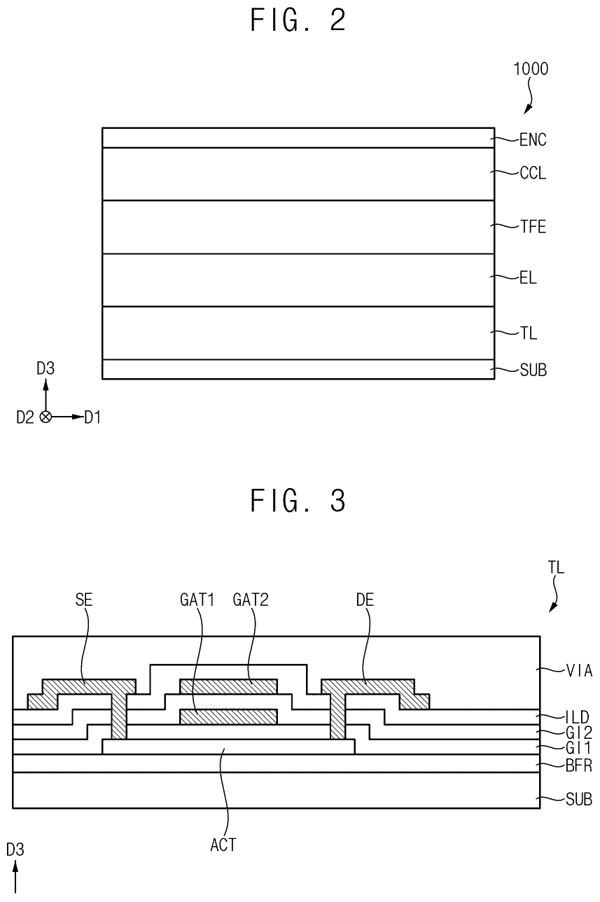

FIG. 1 is a plan view illustrating a display device according to an embodiment of the present invention. FIG. 2 is a cross-sectional view illustrating the display device of FIG. 1.

Referring to FIG. 1, a display device 1000 according to an embodiment of the present invention may include at least one pixel, and the pixel may include at least one sub-pixel. For example, the display device 1000 may include a plurality of pixels, and each of pixels may include a first sub-pixel SPX1, a second sub-pixel SPX2, and a third sub-pixel SPX3. Each of the pixels may be formed in the same structure and may be arranged in a matrix form along a first direction D1 and a second direction D2 that intersects the first direction D1. In addition, each of the pixels may have a thickness in a third direction D3 that is substantially perpendicular to the first and second directions D1 and D2.

In an embodiment of the present invention, the first sub-pixel SPX1 may emit blue light, and the second sub-pixel SPX2 may emit red light. Further, the third sub-pixel SPX3 may emit green light. The display device 1000 may display an image by combining colors that are emitted from the first to third sub-pixels SPX1, SPX2, and SPX3.

In an embodiment of the present invention, the display device 1000 may include a 1-1 auxiliary electrode AE1-1, a 1-2 auxiliary electrode AE1-2, a 2-1 auxiliary electrode AE2-1, a second auxiliary electrode AE2-2, a 3-1 auxiliary electrode AE3-1, and a 3-2 auxiliary electrode AE3-2. For example, the 1-1 auxiliary electrode AE1-1 and the 1-2 auxiliary electrode AE1-2 may correspond to the first sub-pixel SPX1, and the 2-1 auxiliary electrode AE2-1 and the 2-2 auxiliary electrode AE2-2 may correspond to the second sub-pixel SPX2. Further, the 3-1 auxiliary electrode AE3-1 and the 3-2 auxiliary electrode AE3-2 may correspond to the third sub-pixel SPX3.

Referring to FIG. 2, the display device 1000 may include a substrate SUB, a transistor layer TL, an emission layer EL, a thin film encapsulation layer TFE, a color conversion layer CCL, and a glass encapsulation layer ENC. The transistor layer TL, the emission layer EL, the thin film encapsulation layer TFE, the color conversion layer CCL, and the glass encapsulation layer ENC may be sequentially stacked on the substrate SUB.

The transistor layer TL may generate a driving current, and the emission layer EL may emit light corresponding to the driving current. The thin film encapsulation layer TFE may prevent moisture and external air from penetrating into the emission layer EL. The color conversion layer CCL may convert the color of light that is emitted from the emission layer EL, and the glass encapsulation layer ENC may protect the emission layer EL and the color conversion layer CCL from impact.

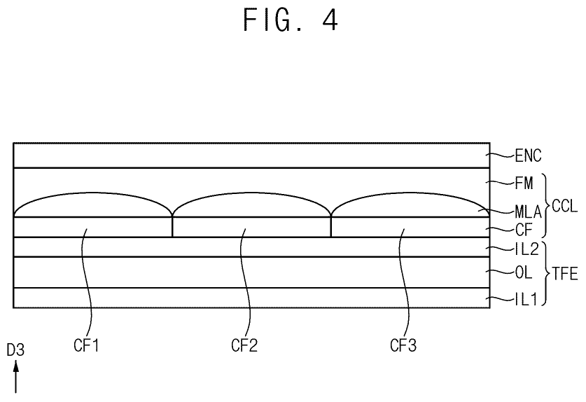

FIG. 3 is a cross-sectional view illustrating a transistor layer included in the display device of FIG. 2. FIG. 4 is a cross-sectional view illustrating a thin film encapsulation layer, a color conversion layer, and a glass encapsulation layer included in the display device of FIG. 2.

Referring to FIG. 3, the transistor layer TL may include a buffer layer BFR, an active pattern ACT, a first gate insulating layer GI1, a first gate electrode GAT1, a second gate insulating layer GI2, a second gate electrode GAT2, an interlayer insulating layer ILD, a source electrode SE, a drain electrode DE, and a via insulating layer VIA.

In an embodiment of the present invention, the substrate SUB may be formed of glass, quartz, plastic, etc. Examples of materials that can be used as the plastic may include polyimide (PI), polyacrylate, polymethylmethacrylate (PMMA), polycarbonate (PC), polyethylenenaphthalate. PEN, polyvinylidene chloride, polyvinylidene difluoride (PVDF), polystyrene, ethylene vinylalcohol copolymer, polyethersulphone (PES), poly ether imide (PEI), polyphenylene sulfide (PPS), polyallylate, tri-acetyl cellulose (TAC), cellulose acetate propionate (CAP), etc. These materials can be used alone or in combination with each other.

The buffer layer BFR may be disposed on the substrate SUB. In an embodiment of the present invention, the buffer layer BFR may be formed of an inorganic material. Examples of materials that can be used as the inorganic material may include silicon oxide, silicon nitride, and silicon oxynitride. These materials can be used alone or in combination with each other. The buffer layer BFR may prevent metal atoms or impurities from penetrating into the active pattern ACT. In addition, the buffer layer BFR may control the rate of heat provision during the crystallization process to form the active pattern ACT.

The active pattern ACT may be disposed on the buffer layer BFR. In an embodiment of the present invention, the active pattern ACT may be formed of a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may include InGaZnO (IGZO), InSnZnO (ITZO), etc. In addition, the oxide semiconductor material may include, for example, indium (In), gallium (Ga), tin (Sn), zirconium (Zr), vanadium (V), hafnium (Hf), cadmium (Cd), germanium (Ge), and chromium (Cr).), titanium (Ti), zinc (Zn), etc. These materials can be used alone or in combination with each other.

The first gate insulating layer GI1 may be disposed on the buffer layer BFR and may cover the active pattern ACT. In an embodiment of the present invention, the first gate insulating layer GI1 may be formed of an insulating material. Examples of insulating materials that can be used as the first gate insulating layer GI1 may include silicon oxide, silicon nitride, and silicon oxynitride. These materials can be used alone or in combination with each other.

The first gate electrode GAT1 may be disposed on the first gate insulating layer GI1. In an embodiment of the present invention, the first gate electrode GAT1 may be formed of metal, alloy, conductive metal oxide, transparent conductive material, etc. Examples of materials that can be used as the first gate electrode GAT1 may include silver (Ag), an alloy including silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These materials can be used alone or in combination with each other.

The second gate insulating layer GI2 may be disposed on the first gate insulating layer GI1 and may cover the first gate electrode GAT1. In an embodiment of the present invention, the second gate insulating layer GI2 may be formed of an insulating material.

The second gate electrode GAT2 may be disposed on the second gate insulating layer GI2. In an embodiment of the present invention, the second gate electrode GAT2 may be formed of metal, alloy, conductive metal oxide, transparent conductive material, etc.

The interlayer insulating layer ILD may be disposed on the second gate insulating layer GI2 and may cover the second gate electrode GAT2 and the second gate insulating layer GI2. In an embodiment of the present invention, the interlayer insulating layer ILD may be formed of an insulating material.

The source electrode SE and the drain electrode DE may be disposed on the interlayer insulating layer ILD. In an embodiment of the present invention, the source electrode SE and the drain electrode DE may contact the active pattern ACT by penetrating the interlayer insulating layer ILD, the second gate insulating layer GI2, and the first gate insulating layer GI1. The source electrode SE and the drain electrode DE may be formed of a metal, an alloy, a conductive metal oxide, a transparent conductive material, etc.

The via insulating layer VIA may be disposed on the interlayer insulating layer ILD and may cover the source electrode SE and the drain electrode DE. In an embodiment of the present invention, the via insulating layer VIA may be formed of an organic material. Examples of the organic material may include photoresist, polyacrylic resin, polyimide resin, and acrylic resin. These materials can be used alone or in combination with each other. Accordingly, the via insulating layer VIA may have a substantially flat top surface.

Referring to FIG. 4, the thin film encapsulation layer TFE may include a first inorganic layer IL1, an organic layer OL, and a second inorganic layer IL2. The color conversion layer CCL may include a color filter layer CF, a micro lens array MLA, and a filler FM.

The first inorganic layer IL1 may be disposed on the via insulating layer VIA. In an embodiment of the present invention, the first inorganic layer IL1 may be formed of an inorganic material. The first inorganic layer IL1 may include, for example, silicon oxide, silicon nitride, and silicon oxynitride. These materials can be used alone or in combination with each other.

The organic layer OL may be disposed on the first inorganic layer IL1. In an embodiment of the present invention, the organic layer OL may be formed of an organic material. Examples of the organic material may include photoresist, polyacrylic resin, polyimide resin, and acrylic resin. These materials can be used alone or in combination with each other.

The second inorganic layer IL2 may be disposed on the organic layer OL and may be formed of substantially the same material as the first inorganic layer IL1.

The color filter layer CF may include a first color filter CF1, a second color filter CF2, and a third color filter CF3. The first color filter CF1 may convert the color of light emitted from the emission layer EL into blue. The second color filter CF2 may convert the color of light emitted from the emission layer EL into red, and the third color filter CF3 may convert the color of light emitted from the emission layer EL to green.

In other words, the first color filter CF1 may correspond to the first sub-pixel SPX1. Further, the second color filter CF2 may correspond to the second sub-pixel SPX2, and the third color filter CF3 may correspond to the third sub-pixel SPX3.

The micro lens array MLA may include a plurality of micro lenses. The micro lens array MLA may create a virtual image from images that is provided from the emission layer EL and the color filter layer CF, and may project the virtual image to the user's eyes.

The filler FM may protect the color filter layer CF and the micro lens array MLA from impact, and may include a liquid polymer.

The glass encapsulation layer ENC may be made of glass and may protect underlying components from impact. However, the glass encapsulation layer ENC may include other materials in addition to glass.

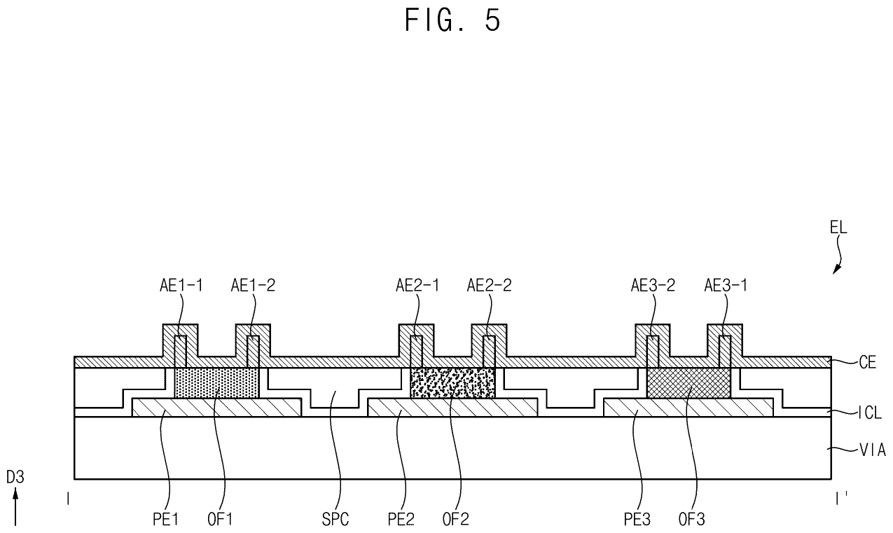

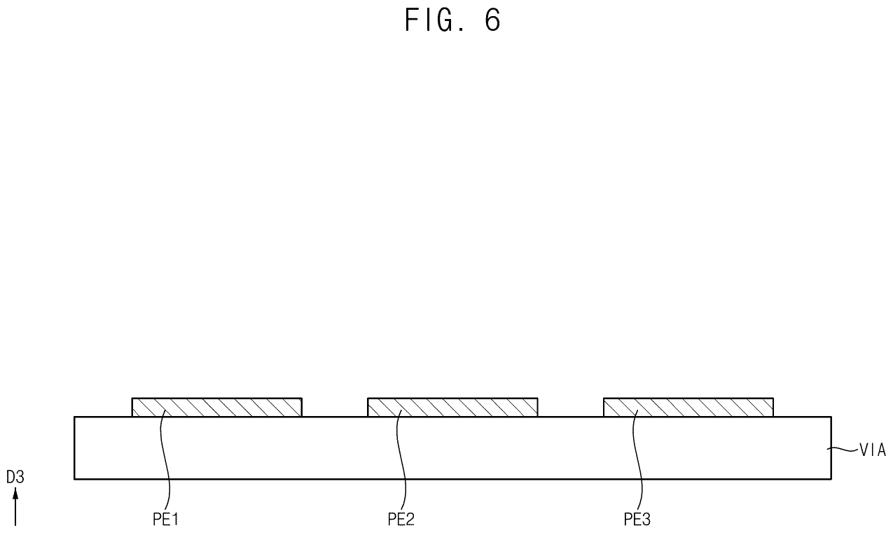

FIG. 5 is a cross-sectional view illustrating an emission layer included in the display device of FIG. 2. FIGS. 6 to 32 are cross-sectional views illustrating a method of manufacturing the emission layer of FIG. 5. For example, FIG. 5 is a cross-sectional view taken along line I-I′ of FIG. 1.

Referring to FIG. 5, the emission layer EL may include a first pixel electrode PE1, a second pixel electrode PE2, a third pixel electrode PE3, a first organic functional layer OF1, a second organic functional layer OF2, a third organic functional layer OF3, an inorganic capping layer ICL, a spacer SPC, a 1-1 auxiliary electrode AE1-1, a 1-2 auxiliary electrode AE1-2, a 2-1 auxiliary electrode AE2-1, a 2-2 auxiliary electrode AE2-2, a 3-1 auxiliary electrode AE3-1, a 3-2 auxiliary electrode AE3-2, and a common electrode CE.

The first pixel electrode PE1 may be disposed on the via insulating layer VIA. The first pixel electrode PE1 may be formed of metal, alloy, metal oxide, reflective conductive material, etc. Examples of materials that can be used as the first pixel electrode PE1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These materials can be used alone or in combination with each other.

The second pixel electrode PE2 and the third pixel electrode PE3 may be disposed on the via insulating layer VIA. In an embodiment of the present invention, each of the second pixel electrode PE2 and the third pixel electrode PE3 may be spaced apart from the first pixel electrode PE1 and may be formed simultaneously with the first pixel electrode PE1.

The first organic functional layer OF1 may be disposed on the first pixel electrode PE1. In an embodiment of the present invention, the first organic functional layer OF1 may include a blue emission layer and at least one common layer. For example, the common layer may include a hole transport layer, an electron transport layer, a charge generation layer, etc. The first pixel electrode PE1 and the first organic functional layer OF1 may correspond to the first sub-pixel SPX1.

The second organic functional layer OF2 may be disposed on the second pixel electrode PE2. In an embodiment of the present invention, the second organic functional layer OF2 may include a red emission layer and the common layer. The second pixel electrode PE2 and the second organic functional layer OF2 may correspond to the second sub-pixel SPX2.

The third organic functional layer OF3 may be disposed on the third pixel electrode PE3. In an embodiment of the present invention, the third organic functional layer OF3 may include a green emission layer and the common layer. The third pixel electrode PE3 and the third organic functional layer OF3 may correspond to the third sub-pixel SPX3.

The inorganic capping layer ICL may be disposed on the via insulating layer VIA. In an embodiment of the present invention, the inorganic capping layer ICL may cover the first to third pixel electrodes PE1, PE2, and PE3 and the first to third organic functional layers OF1, OF2, and OF3, and may contact the first to third pixel electrodes PE1, PE2, and PE3 and the first to third organic functional layers OF1, OF2, and OF3.

In an embodiment of the present invention, the inorganic capping layer ICL may be formed of an inorganic material. Examples of materials that can be used as the inorganic material may include silicon oxide, silicon nitride, and silicon oxynitride. These materials can be used alone or in combination with each other.

In an embodiment of the present invention, the inorganic capping layer ICL may be formed along the profile of the bottoms of the first, second, and third pixel electrodes PE1, PE2, and PE3 and may have a substantially constant thickness. For example, the inorganic capping layer ICL may have a thickness of about 1000 Å.

The spacer SPC may be disposed on the via insulating layer VIA. In an embodiment of the present invention, the spacer SPC may be disposed between the first to third pixel electrodes PE1, PE2, and PE3 and may be disposed on the inorganic capping layer ICL. For example, the spacer SPC may contact the inorganic capping layer ICL. In addition, the spacer SPC may be spaced apart from the first to third pixel electrodes PE1, PE2, and PE3 and the first to third organic functional layers OF1, OF2, and OF3 without contacting them. For example, inorganic capping layer ICL may be disposed between the first to third pixel electrodes PE1, PE2, and PE3 and the spacer SPC and between the first to third organic functional layers OF1, OF2, and OF3 and the spacer SPC.

In an embodiment of the present invention, the spacer SPC may be formed of an organic material. Examples of the organic material may include a photoresist, a polyacrylic resin, a polyimide resin, and an acrylic resin. These materials can be used alone or in combination with each other. Accordingly, the spacer SPC may have a substantially flat top surface.

In an embodiment of the present invention, the 1-1 auxiliary electrode AE1-1 and the 1-2 auxiliary electrode AE1-2 may be disposed on the first organic functional layer OF1.

In an embodiment of the present invention, the 1-1 auxiliary electrode AE1-1 may overlap the first organic functional layer OF1 and may overlap one side of the first organic functional layer OF1. For example, as shown in FIG. 1, the 1-1 auxiliary electrode AE1-1 may extend in the second direction D2.

In an embodiment of the present invention, as the 1-1 auxiliary electrode AE1-1 is patterned together with the first organic functional layer OF1, a boundary of the 1-1 auxiliary electrode AE1-1 may coincides with a boundary of the first organic functional layer OF1. For example, a side surface of the 1-1 auxiliary electrode AE1-1 may be coplanar with a side surface of the first organic functional layer OF1. In addition, the 1-1 auxiliary electrode AE1-1 might not overlap the central portion of the first organic functional layer OF1.

In an embodiment of the present invention, the 1-1 auxiliary electrode AE1-1 may be spaced apart from the inorganic capping layer ICL and the spacer SPC. In other words, the 1-1 auxiliary electrode AE1-1 might not contact the inorganic capping layer ICL and the spacer SPC.

In an embodiment of the present invention, the 1-2 auxiliary electrode AE1-2 may overlap the first organic functional layer OF1, and may overlap the other side opposite to the one side of the first organic functional layer OF1. For example, as shown in FIG. 1, the 1-2 auxiliary electrode AE1-2 may extend in the second direction D2, and may be opposed to the 1-1 auxiliary electrode AE1-1.

In an embodiment of the present invention, as the 1-2 auxiliary electrode AE1-2 is patterned together with the first organic functional layer OF1, a boundary of the 1-2 auxiliary electrode AE1-2 may coincides with a boundary of the first organic functional layer OF1. For example, a side surface of the 1-2 auxiliary electrode AE1-2 may be coplanar with a side surface of the first organic functional layer OF1. In addition, the 1-2 auxiliary electrode AE1-2 might not overlap the central portion of the first organic functional layer OF1.

In an embodiment of the present invention, the 1-2 auxiliary electrode AE1-2 may be spaced apart from the inorganic capping layer ICL and the spacer SPC. In other words, the 1-2 auxiliary electrode AE1-2 might not contact the inorganic capping layer ICL and the spacer SPC.

In an embodiment of the present invention, the 2-1 auxiliary electrode AE2-1 and the 2-2 auxiliary electrode AE2-2 may be disposed on the second organic functional layer OF2.

In an embodiment of the present invention, the 2-1 auxiliary electrode AE2-1 may overlap the second organic functional layer OF2 and may overlap one side of the second organic functional layer OF2. For example, as shown in FIG. 1, the 2-1 auxiliary electrode AE2-1 may extend in the second direction D2.

In an embodiment of the present invention, as the 2-1 auxiliary electrode AE2-1 is patterned together with the second organic functional layer OF2, a boundary of the 2-1 auxiliary electrode AE2-1 may coincide with a boundary of the second organic functional layer OF2. For example, a side surface of the 2-1 auxiliary electrode AE2-1 may be coplanar with a side surface of the second organic functional layer OF2. In addition, the 2-1 auxiliary electrode AE2-1 might not overlap the central portion of the second organic functional layer OF2.

In an embodiment of the present invention, the 2-1 auxiliary electrode AE2-1 may be spaced apart from the inorganic capping layer ICL and the spacer SPC. In other words, the 2-1 auxiliary electrode AE2-1 might not contact the inorganic capping layer ICL and the spacer SPC.

In an embodiment of the present invention, the 2-2 auxiliary electrode AE2-2 may overlap the second organic functional layer OF2, and may overlap the other side opposite to the one side of the second organic functional layer OF2. For example, as shown in FIG. 1, the 2-2 auxiliary electrode AE2-2 may extend in the second direction D2, and may be opposed to the 2-1 auxiliary electrode AE2-1.

In an embodiment of the present invention, as the 2-2 auxiliary electrode AE2-2 is patterned together with the second organic functional layer OF2, a boundary of the 2-2 auxiliary electrode AE2-2 may coincide with a boundary of the second organic functional layer OF2. For example, a side surface of the 2-2 auxiliary electrode AE2-2 may be coplanar with a side surface of the second organic functional layer OF2. In addition, the 2-2 auxiliary electrode AE2-2 might not overlap the central portion of the second organic functional layer OF2.

In an embodiment of the present invention, the 2-2 auxiliary electrode AE2-2 may be spaced apart from the inorganic capping layer ICL and the spacer SPC. In other words, the 2-2 auxiliary electrode AE2-2 might not contact the inorganic capping layer ICL and the spacer SPC.

In an embodiment of the present invention, the 3-1 auxiliary electrode AE3-1 and the 3-2 auxiliary electrode AE3-2 may be disposed on the third organic functional layer OF3.

In an embodiment of the present invention, the 3-1 auxiliary electrode AE3-1 may overlap the third organic functional layer OF3 and may overlap one side of the third organic functional layer OF3. For example, as shown in FIG. 1, the 3-1 auxiliary electrode AE3-1 may extend in the second direction D2.

In an embodiment of the present invention, as the 3-1 auxiliary electrode AE3-1 is patterned together with the third organic functional layer OF3, a boundary of the 3-1 auxiliary electrode AE3-1 may coincides with a boundary of the third organic functional layer OF3. For example, a side surface of the 3-1 auxiliary electrode AE3-1 may be coplanar with a side surface of the third organic functional layer OF3. In addition, the 3-1 auxiliary electrode AE3-1 might not overlap the central portion of the third organic functional layer OF3.

In an embodiment of the present invention, the 3-1 auxiliary electrode AE3-1 may be spaced apart from the inorganic capping layer ICL and the spacer SPC. In other words, the 3-1 auxiliary electrode AE3-1 might not contact the inorganic capping layer ICL and the spacer SPC.

In an embodiment of the present invention, the 3-2 auxiliary electrode AE3-2 may overlap the third organic functional layer OF3, and may overlap the other side opposite to the one side of the third organic functional layer OF3. For example, as shown in FIG. 1, the 3-2 auxiliary electrode AE3-2 may extend in the second direction D2, and may be opposed to the 3-1 auxiliary electrode AE3-1.

In an embodiment of the present invention, as the 3-2 auxiliary electrode AE3-2 is patterned together with the third organic functional layer OF3, a boundary of the 3-2 auxiliary electrode AE3-2 may coincide with a boundary of the third organic functional layer OF3. For example, a side surface of the 3-2 auxiliary electrode AE3-2 may be coplanar with a side surface of the third organic functional layer OF3. In addition, the 3-2 auxiliary electrode AE3-2 might not overlap the central portion of the third organic functional layer OF3.

In an embodiment of present invention, the 3-2 auxiliary electrode AE3-2 may be spaced apart from the inorganic capping layer ICL and the spacer SPC. In other words, the 3-2 auxiliary electrode AE3-2 might not contact the inorganic capping layer ICL and the spacer SPC.

In an embodiment of the present invention, the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2 may be formed of a metal, an alloy, a conductive metal oxide, a transparent conductive material, etc. Each of the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2 may include at least one of, for example, silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), and indium zinc oxide (IZO). These materials can be used alone or in combination with each other.

In an embodiment of the present invention, the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2 may be formed of Al, Ag, Ti, Mo, etc., which can be subjected to a thermal evaporation process.

In an embodiment of the present invention, a thickness of each of the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2 may be about 3000 Å.

The common electrode CE may be disposed on the first to third organic functional layers OF1, OF2, and OF3 and the above-described auxiliary electrodes. In an embodiment of the present invention, the common electrode CE may cover the first to third organic functional layers OF1, OF2, and OF3. In addition, the common electrode CE may cover the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2.

In an embodiment of the present invention, the 1-1 auxiliary electrode AE1-1 may further contact the common electrode CE. In other words, the 1-1 auxiliary electrode AE1-1 may be interposed between the first organic functional layer OF1 and the common electrode CE.

In addition, the 1-2 auxiliary electrode AE1-2 may be interposed between the first organic functional layer OF1 and the common electrode CE. The 2-1 auxiliary electrode AE2-1 may be interposed between the second organic functional layer OF2 and the common electrode CE. The 2-2 auxiliary electrode AE2-2 may be formed between the second organic functional layer OF2 and the common electrode CE. The 3-1 auxiliary electrode AE3-1 may be interposed between the third organic functional layer OF3 and the common electrode CE. The 3-2 auxiliary electrode AE3-2 may be interposed between the third organic functional layer OF3 and the common electrode CE.

In an embodiment of the present invention, the common electrode CE may be formed of a metal, an alloy, a conductive metal oxide, a transparent conductive material, etc. Examples of materials that can be used as the common electrode CE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These materials can be used alone or in combination with each other.

In an embodiment of the present invention, the common electrode CE may be formed of Ag, Ag containing Yb, or Ag alloy such as AgMg.

In an embodiment of the present invention, the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2 may include the same material as each other.

In an embodiment of the present invention, the 1-1 auxiliary electrode AE1-1 may include the same material as the common electrode CE. In embodiment of the present invention, the 1-1 auxiliary electrode AE1-1 may include a different material from the common electrode CE.

Referring to FIG. 6, the first to third pixel electrodes PE1, PE2, and PE3 may be formed on the via insulating layer VIA. The first to third pixel electrodes PE1, PE2, and PE3 may be spaced apart from each other and may be formed simultaneously.

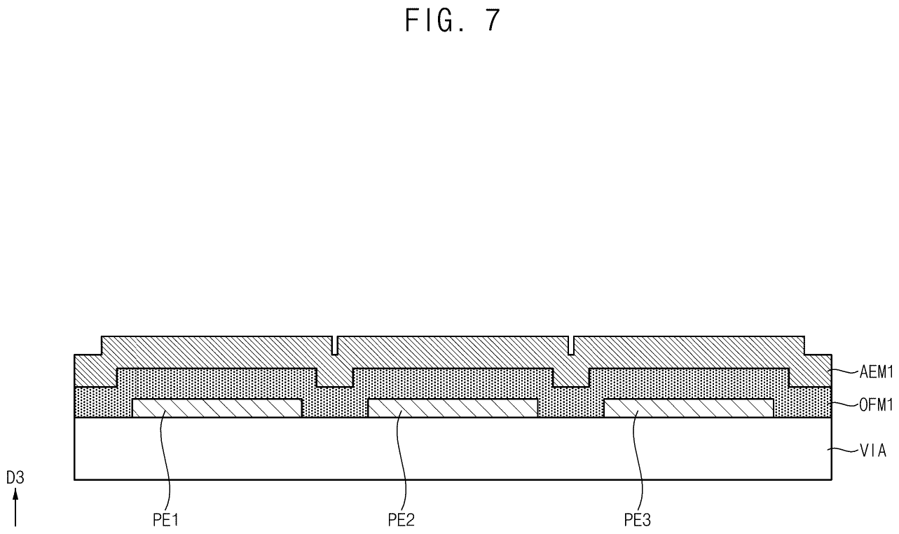

Referring to FIG. 7, a first organic functional material layer OFM1 may be formed on the first to third pixel electrodes PE1, PE2, and PE3, and a first auxiliary electrode material layer AEM1 may be formed on the first organic functional material layer OFM1. In an embodiment of the present invention, the first organic functional material layer OFM1 may be deposited entirely to cover the first to third pixel electrodes PE1, PE2, and PE3. In an embodiment of the present invention, the first auxiliary electrode material layer AEM1 may be deposited entirely to cover the first organic functional material layer OFM1.

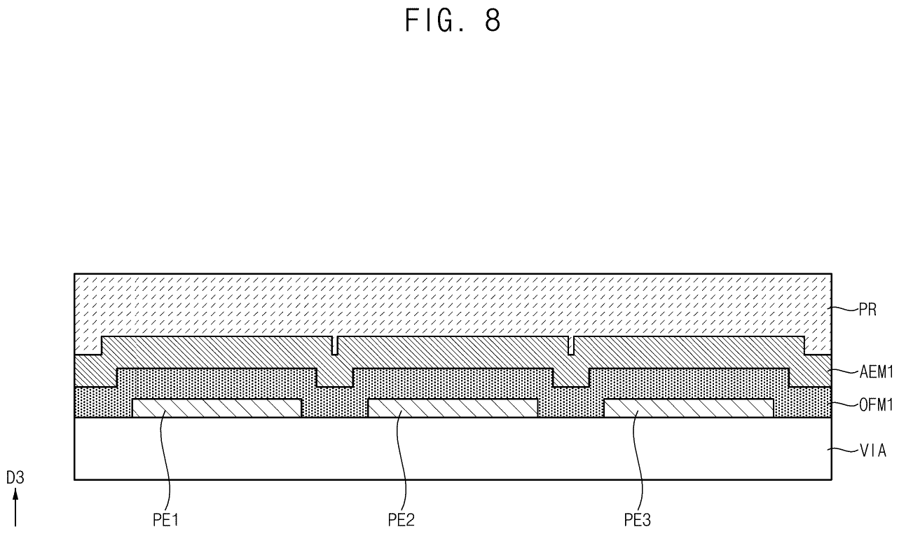

Referring to FIG. 8, a photoresist PR may be coated on the first auxiliary electrode material layer AEM1. The photoresist PR may include a photosensitive organic material.

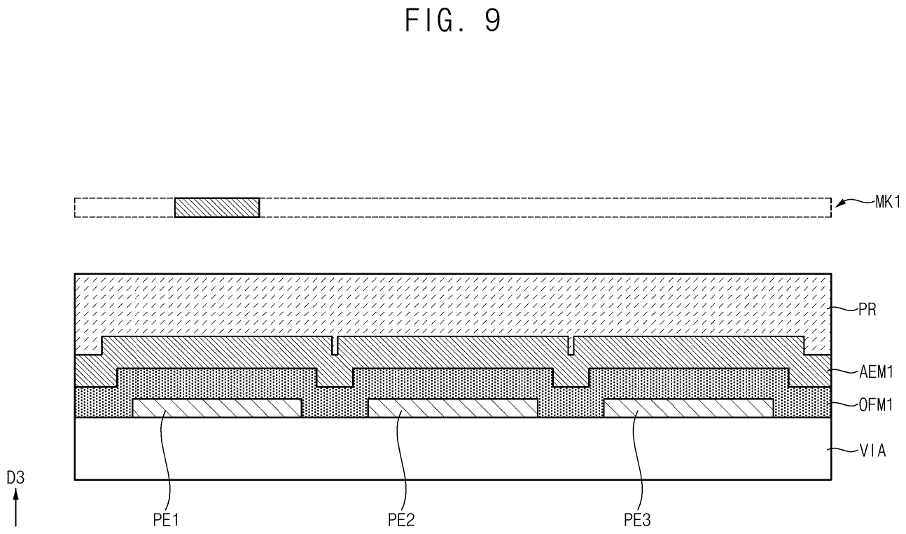

Referring to FIG. 9, a first mask MK1 may be disposed on the photoresist PR. In an embodiment of the present invention, the first mask MK1 may have a pattern that overlaps at least a portion of the first pixel electrode PE1.

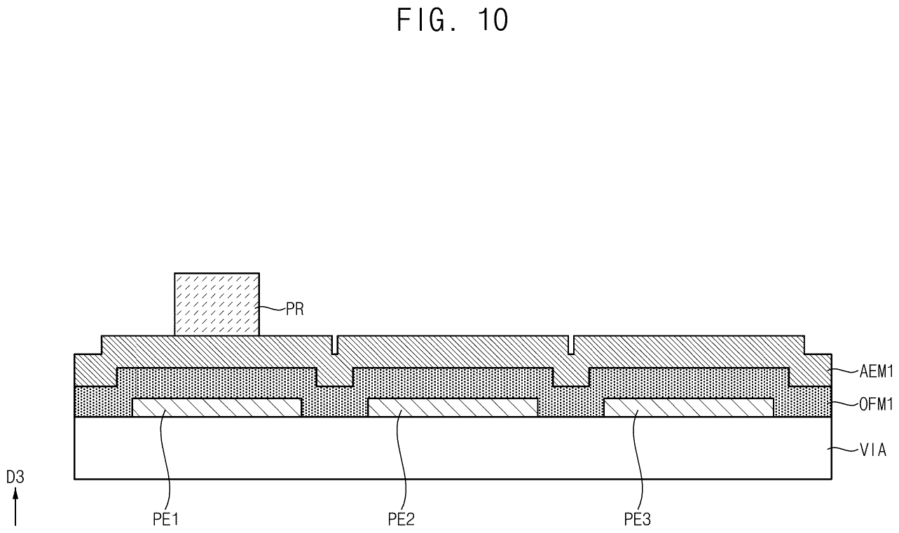

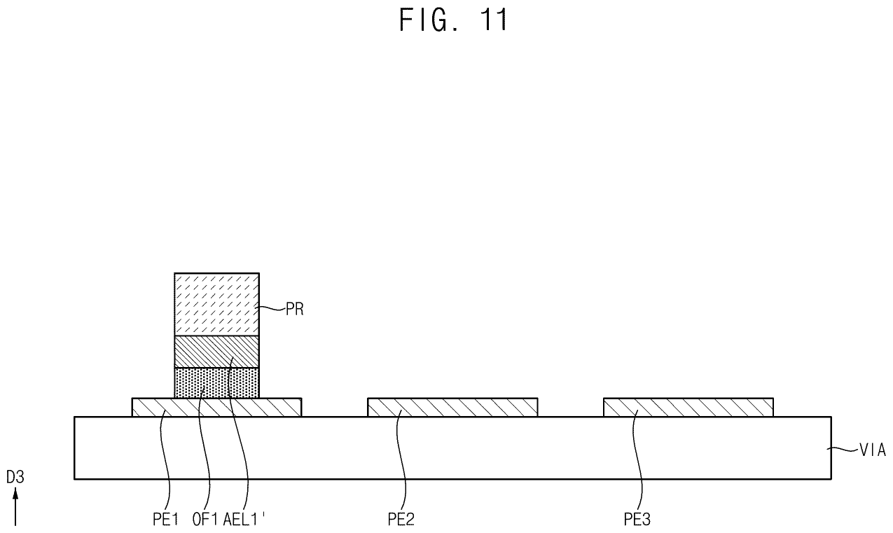

Referring to FIG. 10, the photoresist PR may be patterned according to the pattern of the first mask MK1. Accordingly, the photoresist PR overlapping a portion of the first pixel electrode PE1 may remain.

Referring to FIG. 11, the first organic functional material layer OFM1 and the first auxiliary electrode material layer AEM1 may be patterned together according to the photoresist PR. Accordingly, the first organic functional layer OF1 and a preliminary first auxiliary electrode layer AEL1′ may be formed together.

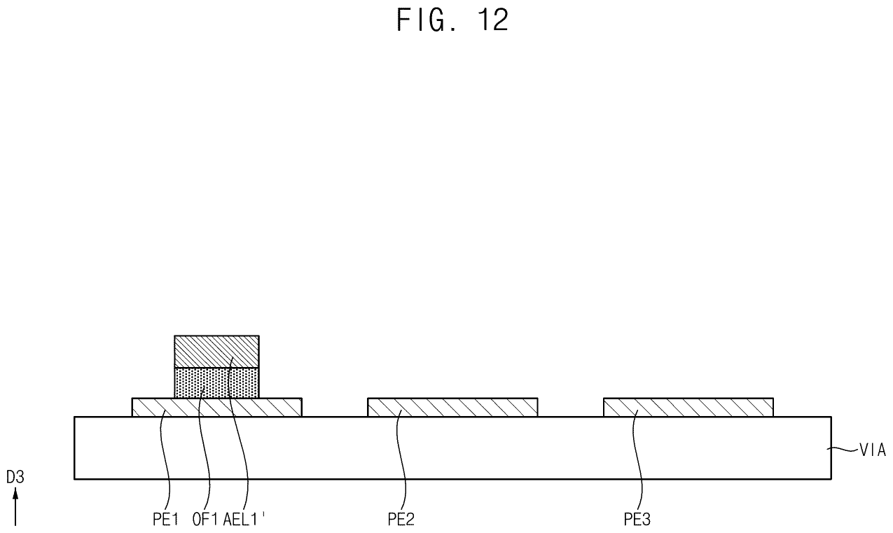

Referring to FIG. 12, the photoresist PR may be removed. The preliminary first auxiliary electrode layer AEL1′ may protect the first organic functional layer OF1 while the first organic functional layer OF1 is formed.

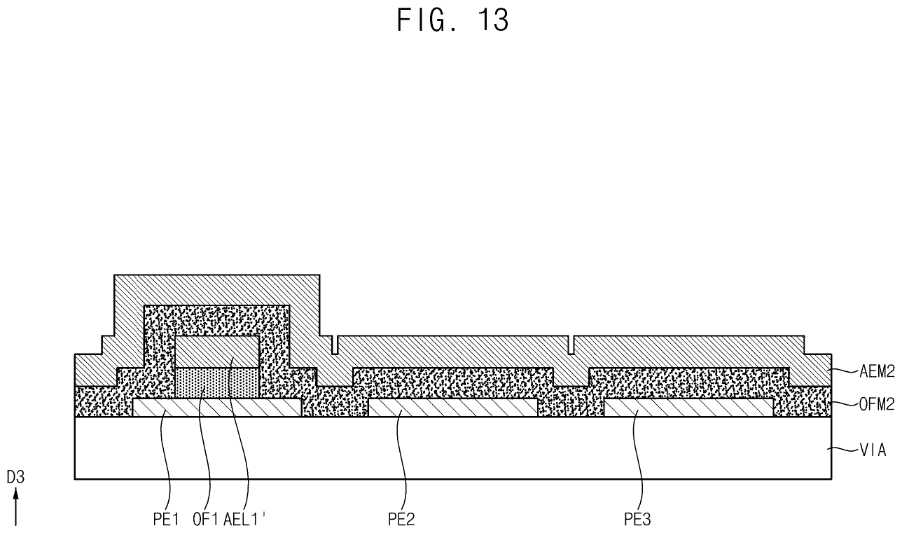

Referring to FIG. 13, the second organic functional material layer OFM2 may be formed on the first organic functional layer OF1, the preliminary first auxiliary electrode layer AEL1′, the second pixel electrode PE2, and the third pixel electrode PE3, and the second auxiliary electrode material layer AEM2 may be formed on the second organic functional material layer OFM2. In an embodiment of the present invention, the second organic functional material layer OFM2 may be deposited entirely to cover the first organic functional layer OF1, the preliminary first auxiliary electrode layer AEL1′, the second pixel electrode PE2, and the third pixel electrode PE3. In an embodiment of the present invention, the second auxiliary electrode material layer AEM2 may be deposited entirely to cover the second organic functional material layer OFM2.

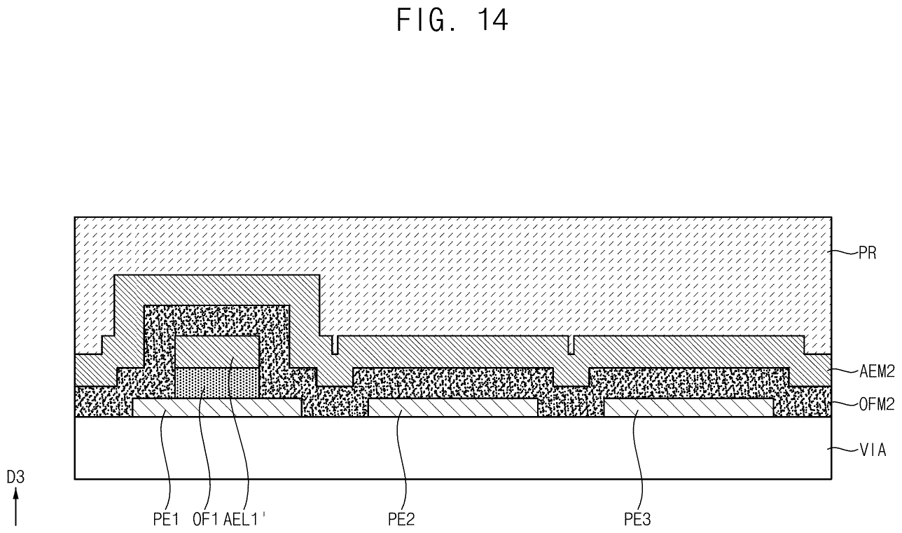

Referring to FIG. 14, a photoresist PR may be coated on the second auxiliary electrode material layer AEM2. The photoresist PR may include a photosensitive organic material.

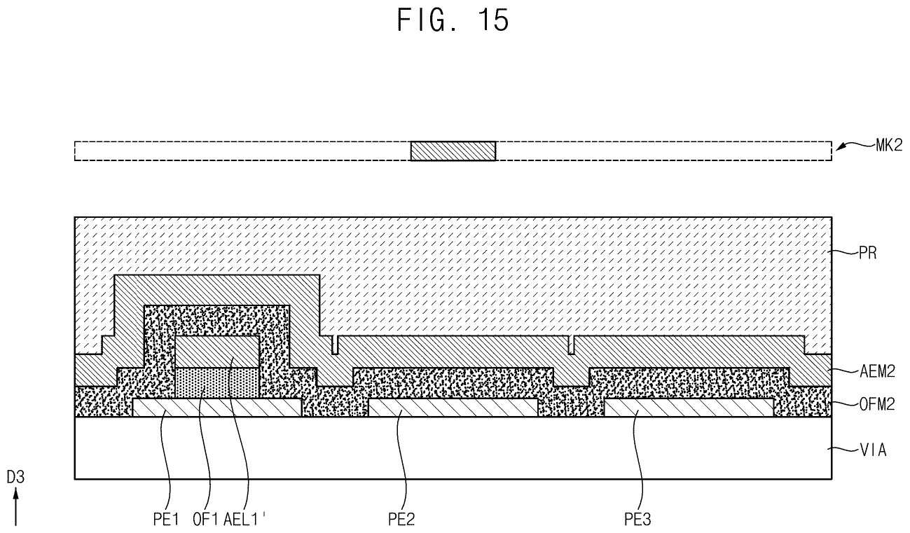

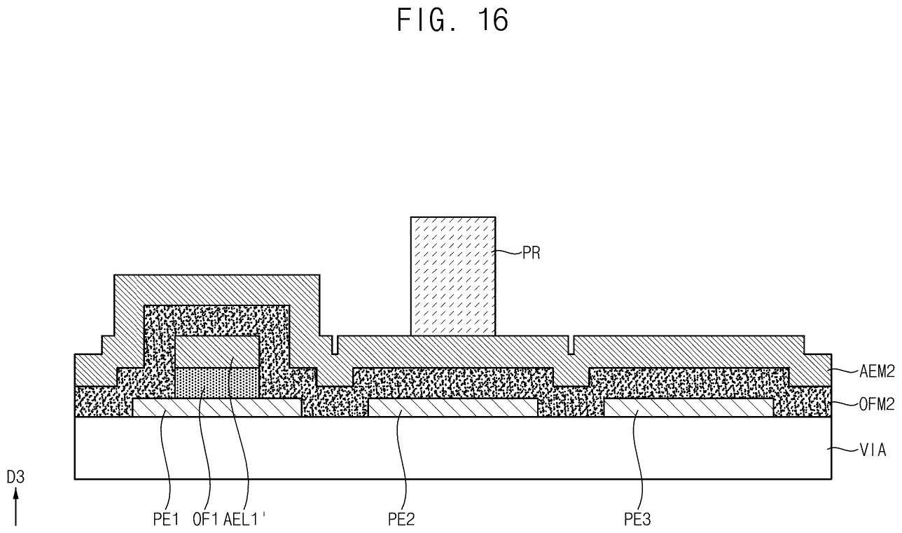

Referring to FIG. 15, a second mask MK2 may be disposed on the photoresist PR. In an embodiment of the present invention, the second mask MK2 may have a pattern that overlaps at least a portion of the second pixel electrode PE2.

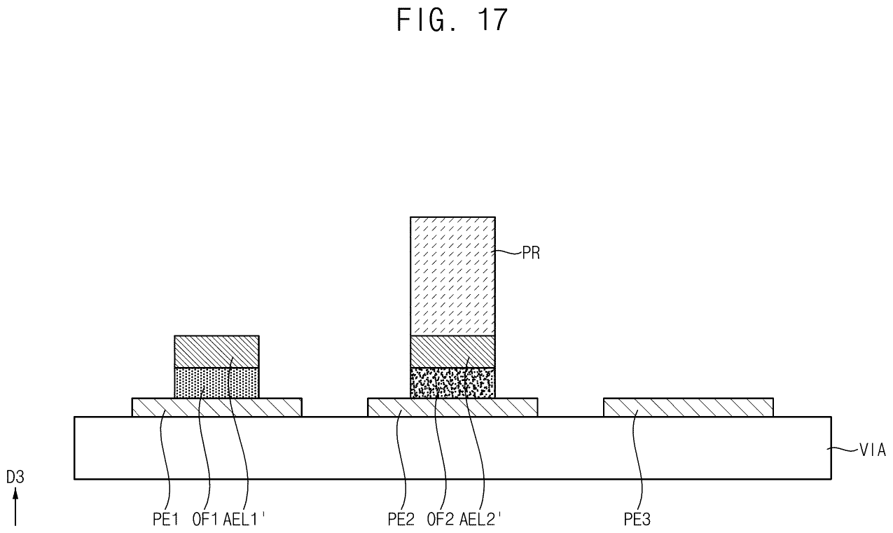

Referring to FIG. 16, the photoresist PR may be patterned according to the pattern of the second mask MK2. Accordingly, the photoresist PR overlapping a portion of the second pixel electrode PE2 may remain.

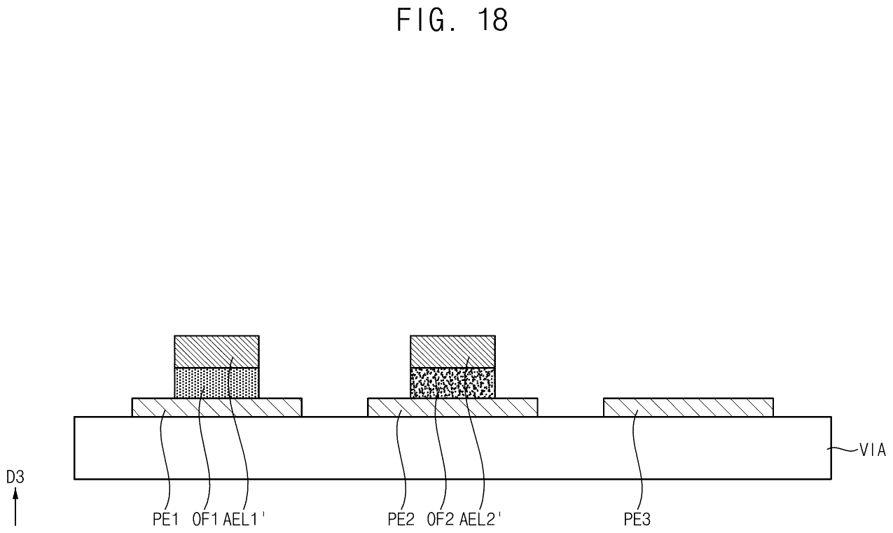

Referring to FIG. 17, the second organic functional material layer OFM2 and the second auxiliary electrode material layer AEM2 may be patterned together according to the photoresist PR. Accordingly, the second organic functional layer OF2 and a preliminary second auxiliary electrode layer AEL2′ may be formed together.

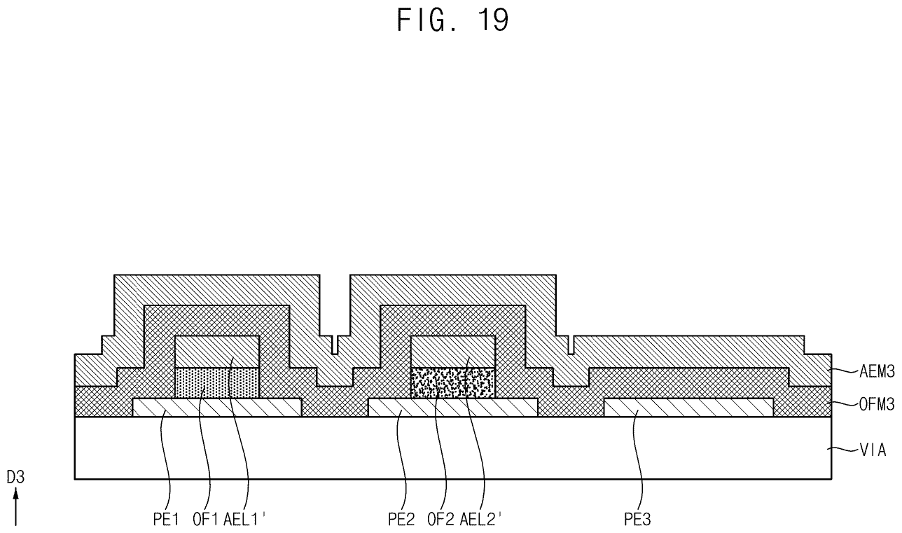

Referring to FIG. 18, the photoresist PR may be removed. The preliminary second auxiliary electrode layer AEL2′ may protect the second organic functional layer OF2 while the second organic functional layer OF2 is formed.

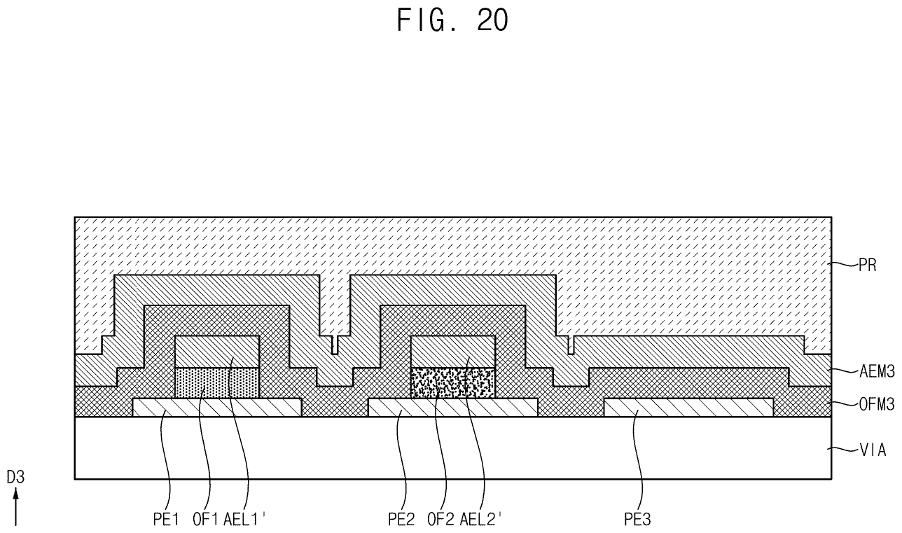

Referring to FIG. 19, the third organic functional material layer OFM3 may be formed on the first organic functional layer OF1, the preliminary first auxiliary electrode layer AEL1′, the second organic functional layer OF2, the preliminary second auxiliary electrode layer AEL2′, and the third pixel electrode PE3, and a third auxiliary electrode material layer AEM3 may be formed on the third organic functional material layer OFM3. In an embodiment of the present invention, the third organic functional material layer OFM3 may be deposited entirely to cover the first organic functional layer OF1, the preliminary first auxiliary electrode layer AEL1′, the second organic functional layer OF2, the preliminary second auxiliary electrode layer AEL2′, and the third pixel electrode PE3. In an embodiment of the present invention, the third auxiliary electrode material layer AEM3 may be deposited entirely to cover the third organic functional material layer OFM3.

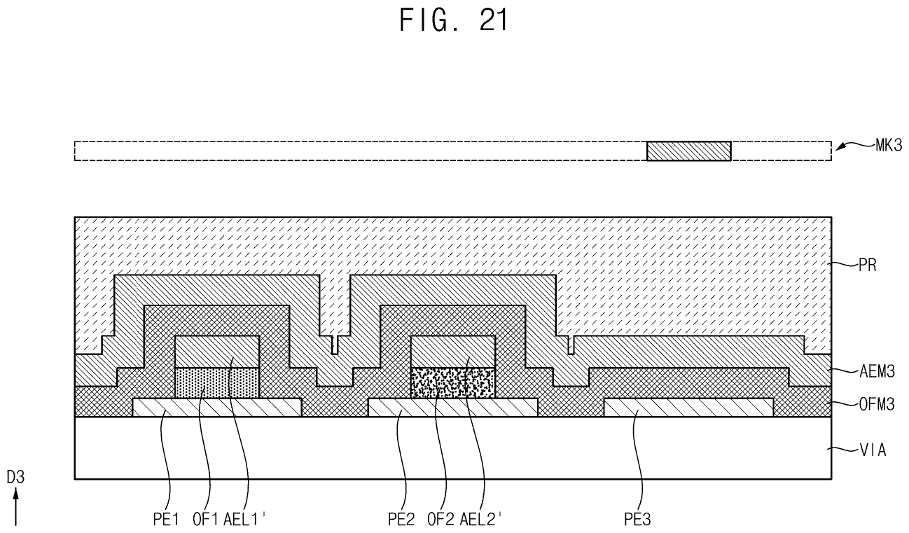

Referring to FIG. 20, a photoresist PR may be coated on the third auxiliary electrode material layer AEM3. The photoresist PR may include a photosensitive organic material.

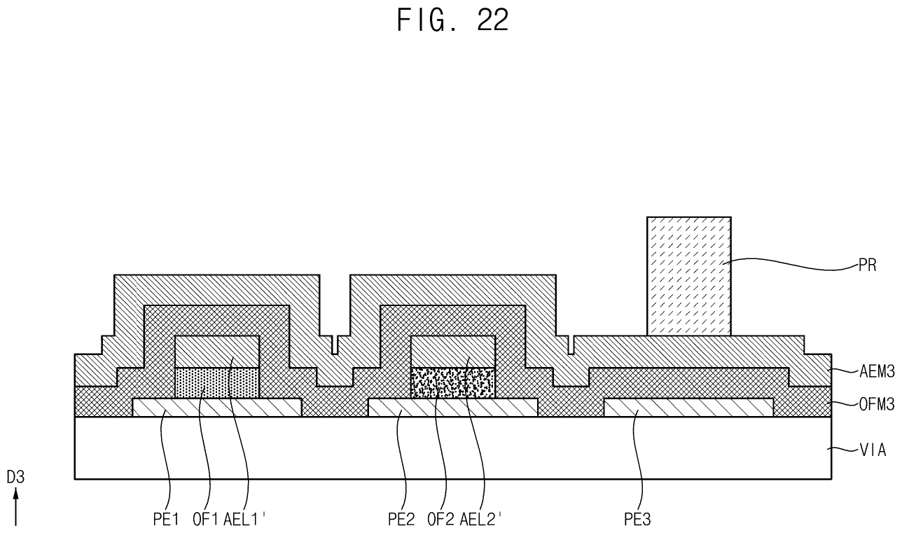

Referring to FIG. 21, a third mask MK3 may be disposed on the photoresist PR. In an embodiment of the present invention, the third mask MK3 may have a pattern that overlaps at least a portion of the third pixel electrode PE3.

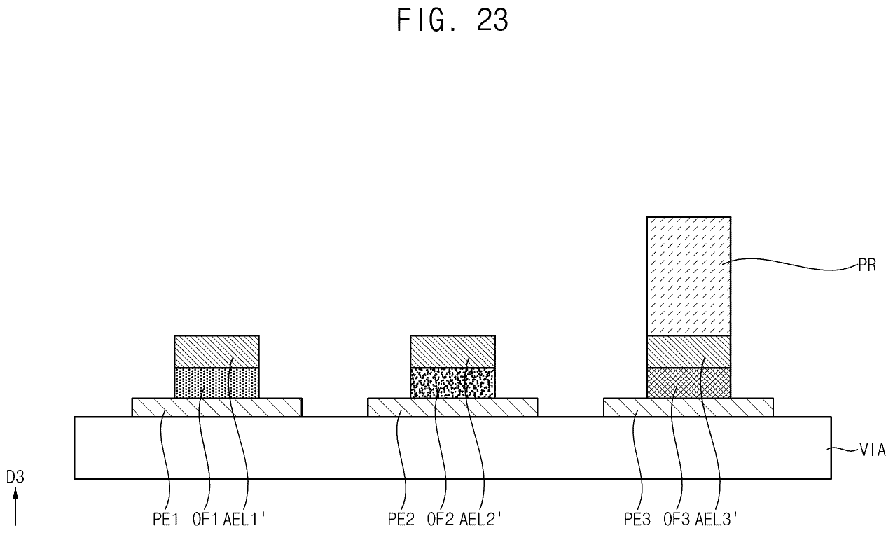

Referring to FIG. 22, the photoresist PR may be patterned according to the pattern of the third mask MK3. Accordingly, the photoresist PR overlapping a portion of the third pixel electrode PE3 may remain.

Referring to FIG. 23, the third organic functional material layer OFM3 and the third auxiliary electrode material layer AEM3 may be patterned together according to the photoresist PR. Accordingly, the third organic functional layer OF3 and a preliminary third auxiliary electrode layer AEL3′ may be formed together.

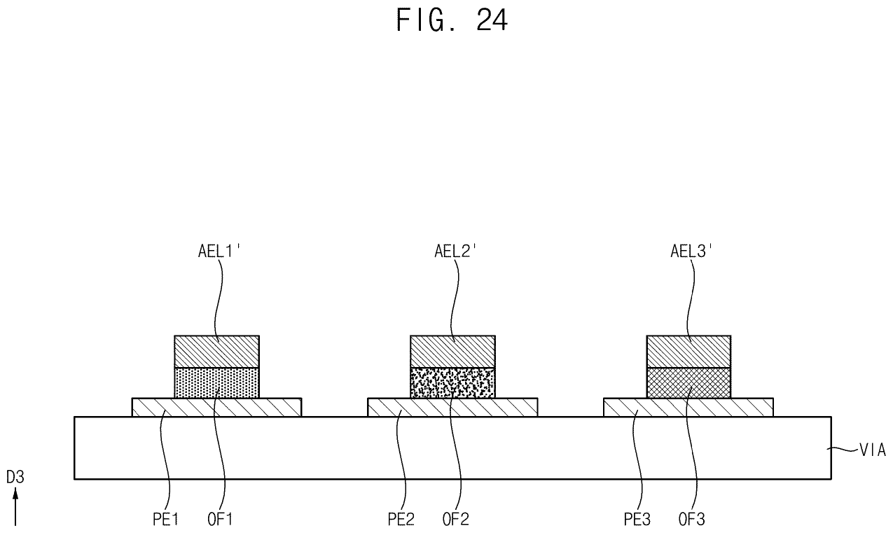

Referring to FIG. 24, the photoresist PR may be removed. The preliminary third auxiliary electrode layer AEL3′ may protect the third organic functional layer OF3 while the third organic functional layer OF3 is formed.

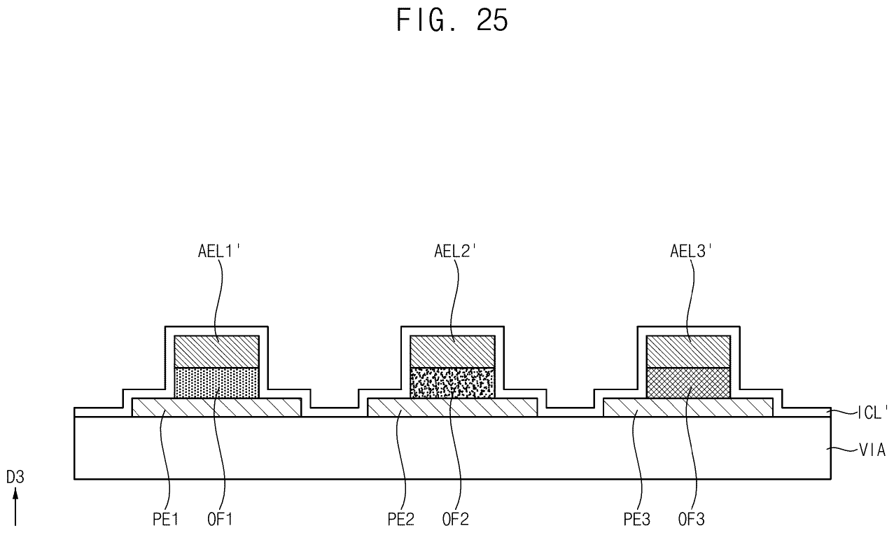

Referring to FIG. 25, a preliminary inorganic capping layer ICL′ may be formed on the preliminary first auxiliary electrode layer AEL1′, the preliminary second auxiliary electrode layer AEL2′, and the preliminary third auxiliary electrode layer AEL3′. In an embodiment of the present invention, the preliminary inorganic capping layer ICL′ may cover the preliminary first auxiliary electrode layer AEL1′, the preliminary second auxiliary electrode layer AEL2′, and the preliminary third auxiliary electrode layer AEL3′, and may contact the preliminary first auxiliary electrode layer AEL1′, the preliminary second auxiliary electrode layer AEL2′, and the preliminary third auxiliary electrode layer AEL3′. In addition, the preliminary inorganic capping layer ICL′ may cover exposed portions of the first to third organic functional layers OF1, OF2, and OF3, exposed portions of the first to third pixel electrodes PE1, PE2, and PE3, and exposed portions of the via insulation layer VIA. In an embodiment of the present invention, the preliminary inorganic capping layer ICL′ may contact the exposed portions of the first to third organic functional layers OF1, OF2, and OF3, the exposed portions of the first to third pixel electrodes PE1, PE2, and PE3, and the exposed portions of the via insulation layer VIA.

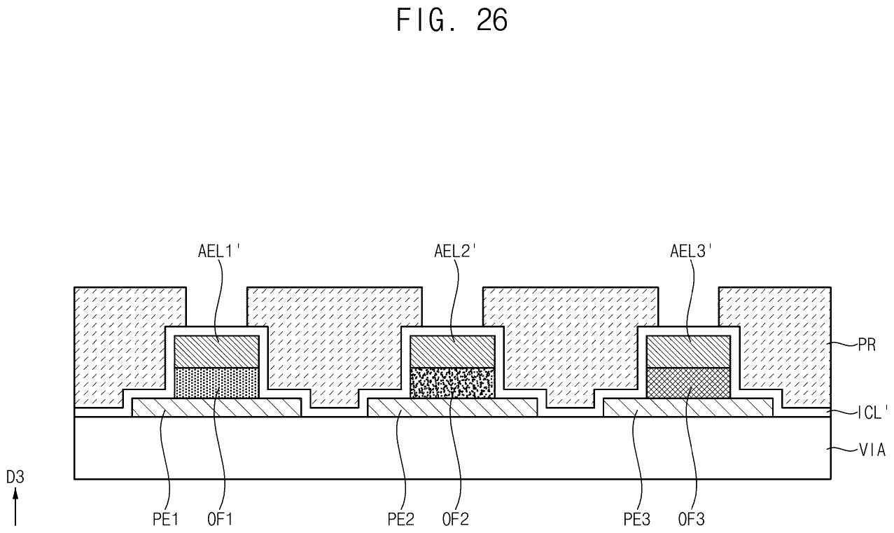

Referring to FIG. 26, a photoresist PR may be coated on the preliminary inorganic capping layer ICL′. The photoresist PR may include the photosensitive organic material. In an embodiment of the present invention, the photoresist PR may expose portions of the preliminary inorganic capping layer ICL′ that overlap the central portion of the first organic functional layer OF1, the central portion of the second organic functional layer OF2, and the central portion of the third organic functional layer OF3.

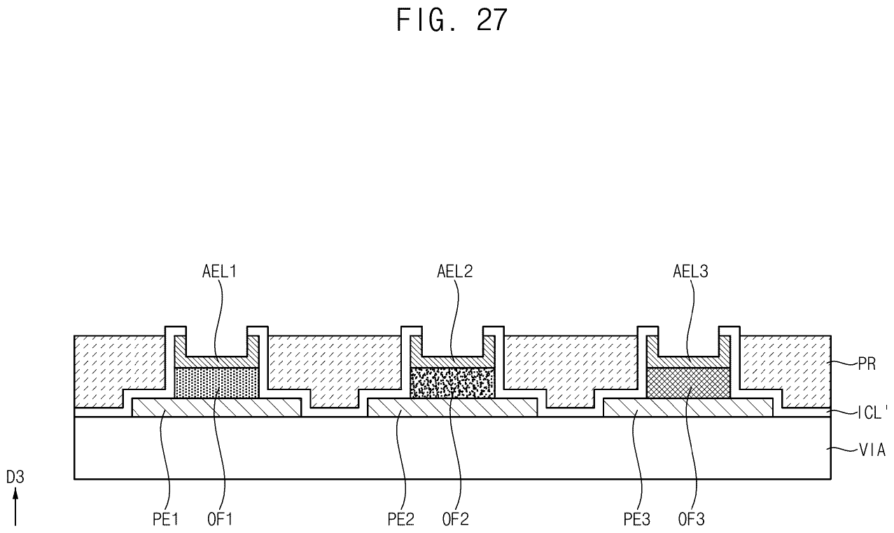

Referring to FIG. 27, a first etch process may be performed. For example, the first etching process may be a dry etching process.

Through the first etching process, the portion of the preliminary inorganic capping layer ICL′ that overlaps the central portion of the first organic functional layer OF1 may be removed. In addition, through the first etching process, a portion of the preliminary first auxiliary electrode layer AEL1′ that overlaps the central portion of the first organic functional layer OF1 may be removed. Accordingly, the first auxiliary electrode layer AEL1 may be formed. A thickness of a portion of the first auxiliary electrode layer AEL1 that overlaps the central portion of the first organic functional layer OF1 may be smaller than a thickness of portions of the first auxiliary electrode layer AEL1 that overlap the sides of the first organic functional layer OF1.

Through the first etching process, the portion of the preliminary inorganic capping layer ICL′ that overlaps the central portion of the second organic functional layer OF2 may be removed. In addition, through the first etching process, a portion of the preliminary second auxiliary electrode layer AEL2′ that overlaps the central portion of the second organic functional layer OF2 may be removed. Accordingly, the second auxiliary electrode layer AEL2 may be formed. A thickness of a portion of the second auxiliary electrode layer AEL2 that overlaps the central portion of the second organic functional layer OF2 may be smaller than a thickness of portions of the second auxiliary electrode layer AEL2 that overlap the sides of the second organic functional layer OF2.

Through the first etching process, the portion of the preliminary inorganic capping layer ICL′ that overlaps the central portion of the third organic functional layer OF3 may be removed. In addition, through the first etching process, a portion of the preliminary third auxiliary electrode layer AEL3′ that overlaps the central portion of the third organic functional layer OF3 may be removed. Accordingly, the third auxiliary electrode layer AEL3 may be formed. A thickness of a portion of the third auxiliary electrode layer AEL3 that overlaps the central portion of the third organic functional layer OF3 may be smaller than a thickness of portions of the third auxiliary electrode layer AEL3 that overlap the sides of the third organic functional layer OF3.

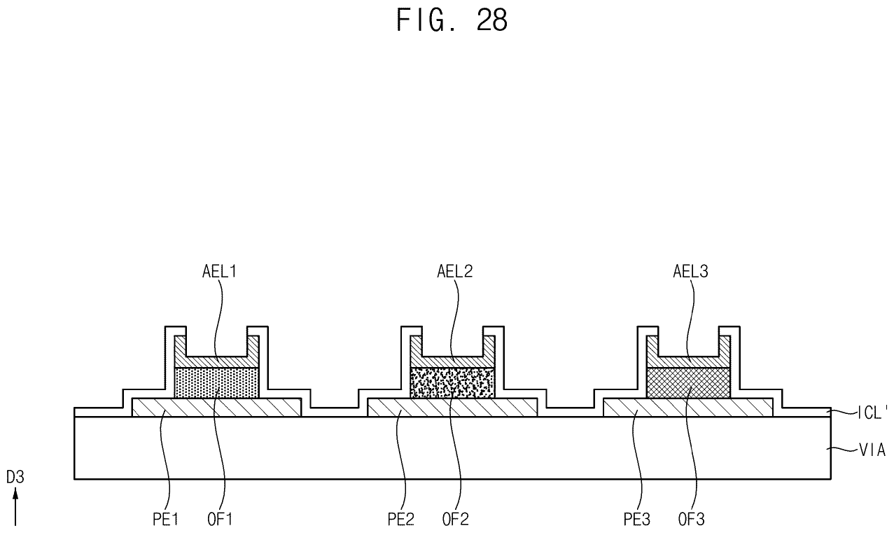

Referring to FIG. 28, the photoresist PR may be removed through an ashing process and a strip process.

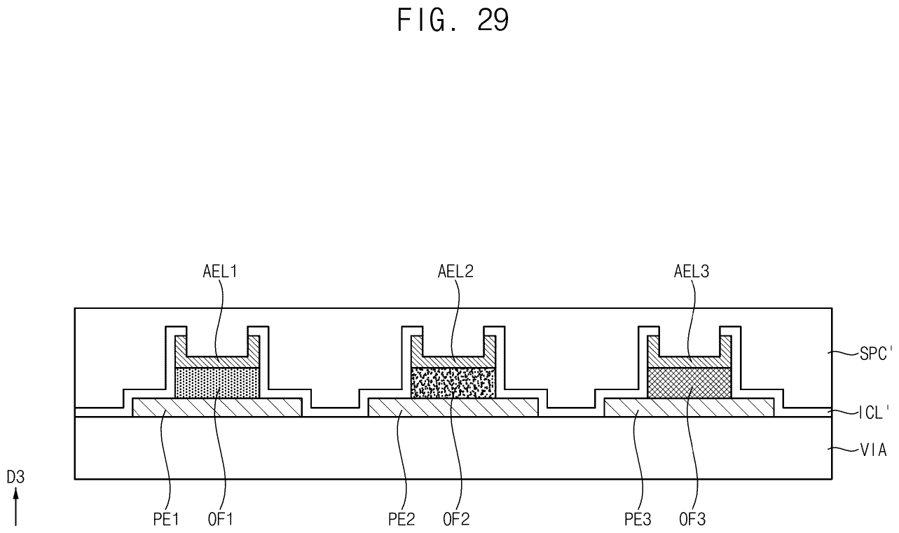

Referring to FIG. 29, a preliminary spacer SPC′ may be formed. In an embodiment of the present invention, the preliminary spacer SPC′ may cover the preliminary inorganic capping layer ICL′, the first auxiliary electrode layer AEL1, the second auxiliary electrode layer AEL2, and the third auxiliary electrode layer AEL3.

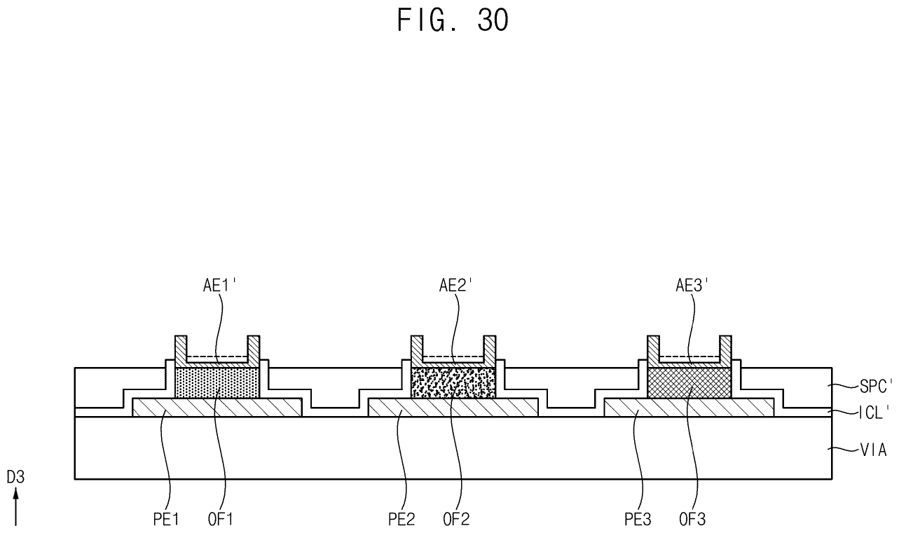

Referring to FIG. 30, a second etch process may be performed. For example, the second etching process may be a dry etching process.

Through the second etching process, the preliminary inorganic capping layer ICL′ overlapping the side of the first auxiliary electrode layer AEL1 may be removed. In addition, through the second etching process, a portion of the first auxiliary electrode layer AEL1 that overlaps the central portion of the first organic functional layer OF1 may be removed. Accordingly, the preliminary first auxiliary electrode AE1′ may be formed. A thickness of the preliminary first auxiliary electrode AE1′ that overlaps the central portion of the first organic functional layer OF1 may be smaller than a thickness of the preliminary first auxiliary electrode AE1′ that overlaps the sides of the first organic functional layer OF1.

Through the second etching process, the preliminary inorganic capping layer ICL′ overlapping the side of the second auxiliary electrode layer AEL2 may be removed. In addition, through the second etching process, a portion of the second auxiliary electrode layer

AEL2 that overlaps the central portion of the second organic functional layer OF2 may be removed. Accordingly, the preliminary second auxiliary electrode AE2′ may be formed. A thickness of the preliminary second auxiliary electrode AE2′ that overlaps the central portion of the second organic functional layer OF2 may be smaller than a thickness of the preliminary second auxiliary electrode AE2′ that overlaps the sides of the second organic functional layer OF2.

Through the second etching process, the preliminary inorganic capping layer ICL′ overlapping the side of the third auxiliary electrode layer AEL3 may be removed. In addition, through the second etching process, a portion of the third auxiliary electrode layer AEL3 that overlaps the central portion of the third organic functional layer OF3 may be removed. Accordingly, the preliminary third auxiliary electrode AE3′ may be formed. A thickness of the preliminary third auxiliary electrode AE3′ that overlaps the central portion of the third organic functional layer OF3 may be smaller than a thickness of the preliminary third auxiliary electrode AE3′ that overlaps the sides of the third organic functional layer OF3.

In an embodiment of the present invention, each of the first to third auxiliary electrode layers AEL1, AEL2, and AEL3 may have a double-layer structure with different etch selectivity. Accordingly, through the second etching process, portions of the first to third auxiliary electrode layers AEL1, AEL2, and AEL3 that overlap the central portions of the first to third organic functional layers OF1, OF2, and OF3, respectively, may remain.

In addition, through the second etching process, a portion of the preliminary spacer SPC′ may be removed.

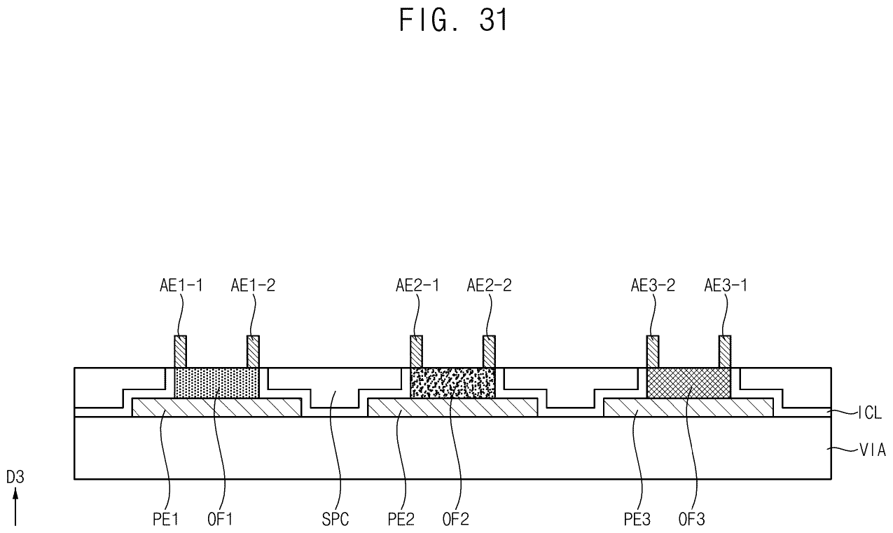

Referring to FIG. 31, a third etching process may be performed. For example, the third etching process may be a wet etching process.

Through the third etching process, the portion of the preliminary first auxiliary electrode AE1′ that overlaps the central portion of the first organic functional layer OF1 may be removed. Accordingly, the 1-1 auxiliary electrode AE1-1 overlapping one side of the first organic functional layer OF1, and the 1-2 auxiliary electrode AE1-2 overlapping the other side of the first organic functional layer OF1 may be formed.

Through the third etching process, the portion of the preliminary second auxiliary electrode AE2′ that overlaps the central portion of the second organic functional layer OF2 may be removed. Accordingly, the 2-1 auxiliary electrode AE2-1 overlapping one side of the second organic functional layer OF2, and the 2-2 auxiliary electrode AE2-2 overlapping the other side of the second organic functional layer OF2 may be formed.

Through the third etching process, the portion of the preliminary third auxiliary electrode AE3′ that overlaps the central portion of the third organic functional layer OF3 may be removed. Accordingly, the 3-1 auxiliary electrode AE3-1 overlapping one side of the third organic functional layer OF3, and the 3-2 auxiliary electrode AE3-2 overlapping the other side of the third organic functional layer OF3 may be formed.

Additionally, through the third etching process, a portion of the preliminary spacer SPC′ may be removed. Accordingly, the spacer SPC may be formed.

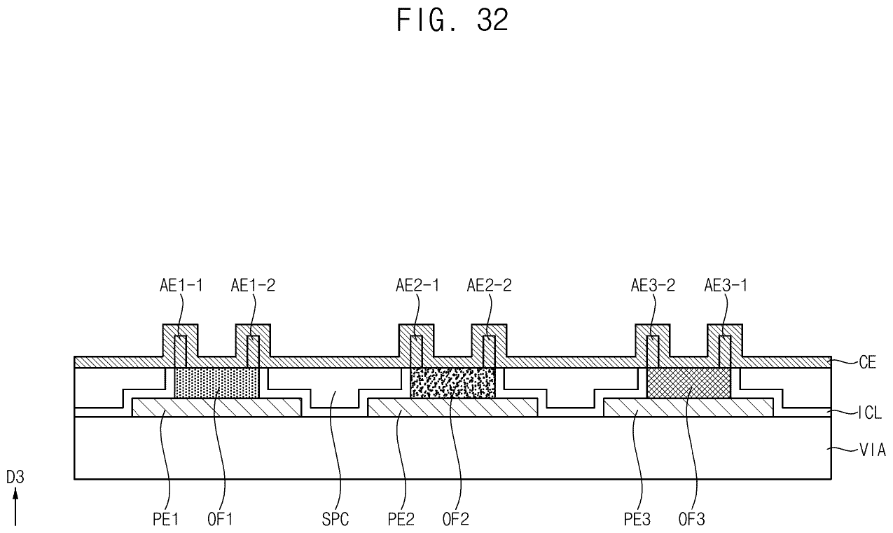

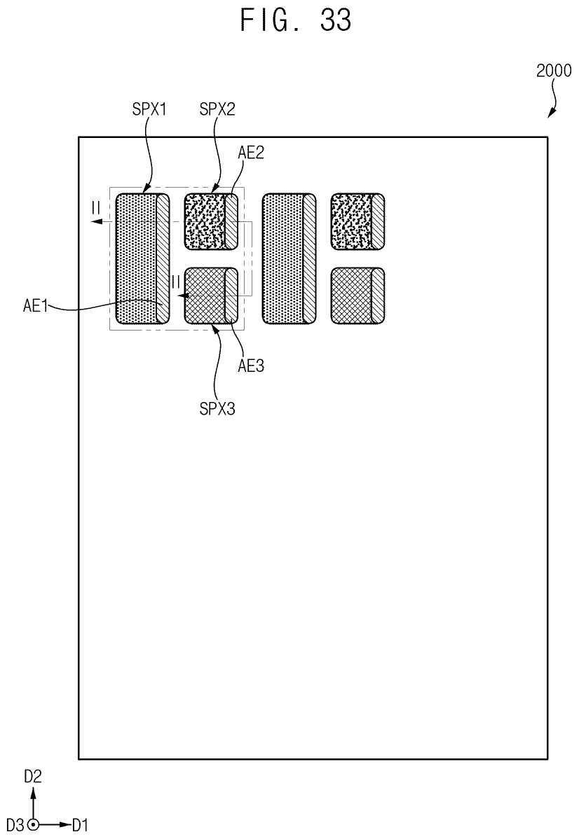

Referring to FIG. 32, a common electrode CE may be formed. As described above, the common electrode CE may cover the first to third organic functional layers OF1, OF2, and OF3. In addition, the common electrode CE may cover the 1-1 auxiliary electrode AE1-1, the 1-2 auxiliary electrode AE1-2, the 2-1 auxiliary electrode AE2-1, the 2-2 auxiliary electrode AE2-2, the 3-1 auxiliary electrode AE3-1, and the 3-2 auxiliary electrode AE3-2.

The display device 1000 according to an embodiment of the present invention may include a pixel electrode, an organic functional layer, a common electrode, and an auxiliary electrode. For example, the display device 1000 may include a first pixel electrode PE1, a first organic functional layer OF1, a common electrode CE, a 1-1 auxiliary electrode AE1-1, and a 1-2 auxiliary electrode AE1-2. The 1-1 auxiliary electrode AE1-1 and the 1-2 auxiliary electrode AE1-2 may be disposed between the first organic functional layer OF1 and the common electrode CE. As the 1-1 auxiliary electrode AE1-1 and the 1-2 auxiliary electrode AE1-2 contact the common electrode CE in a display area of the display device 1000, voltage drop (IR-drop) defects of the common electrode CE can be prevented.

In the method of manufacturing the display device 1000, the 1-1 auxiliary electrode AE1-1 and the 1-2 auxiliary electrode AE1-2 may protect the first organic functional layer OF1. In addition, as the 1-1 auxiliary electrode AE1-1 and the 1-2 auxiliary electrode AE1-2 are patterned together with the first organic functional layer OF1, the boundary of the 1-1 auxiliary electrode AE1-1 may coincide with the boundary of the first organic functional layer OF1, and the boundary of the 1-2 auxiliary electrode AE1-2 may coincide with the boundary of the first organic functional layer OF1. In addition, as the 1-1 auxiliary electrode AE1-1 and the 1-2 auxiliary electrode AE1-2 are patterned together with the first organic functional layer OF1, an additional process for manufacturing the display device 1000 might not be added.

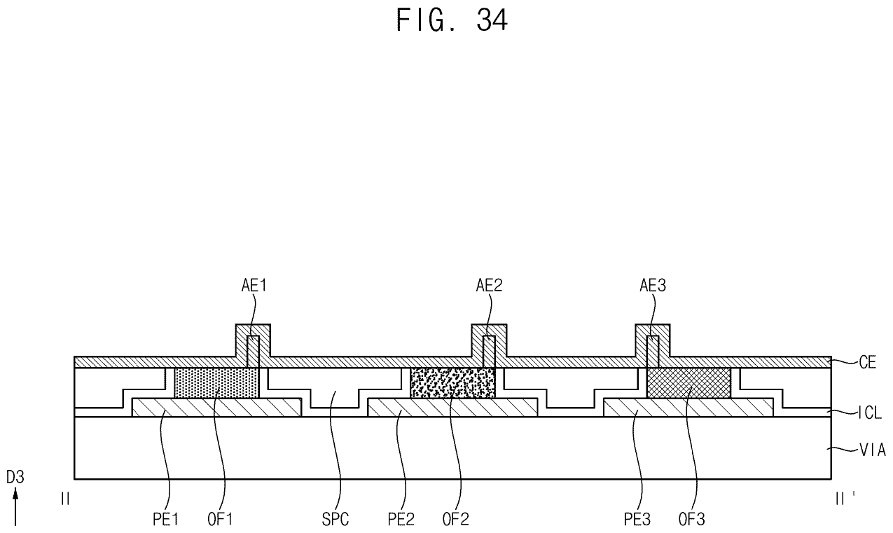

FIG. 33 is a plan view illustrating a display device according to an embodiment of the present invention. FIG. 34 is a cross-sectional view illustrating an emission layer included in the display device of FIG. 33. For example, FIG. 34 is a cross-sectional view taken along line II-II′ of FIG. 33.

Referring to FIG. 33, a display device 2000 according to an embodiment of the present invention may include a first auxiliary electrode AE1, a second auxiliary electrode AE2, and a third auxiliary electrode AE3. However, the display device 2000 may be substantially the same as the display device 1000, except for the first auxiliary electrode AE1, the second auxiliary electrode AE2, and the third auxiliary electrode AE3.

In the display device 2000, the first auxiliary electrode AE1 may correspond to the first sub-pixel SPX1, the second auxiliary electrode AE2 may correspond to the second sub-pixel SPX2, and the third auxiliary electrode AE3 may correspond to the third sub-pixel SPX3.

Referring to FIG. 34, the first auxiliary electrode AE1 may be disposed on the first organic functional layer OF1, and the second auxiliary electrode AE2 may be disposed on the second organic functional layer OF2. Further, the third auxiliary electrode AE3 may be disposed on the third organic functional layer OF3.

In an embodiment of the present invention, the first auxiliary electrode AE1 may overlap the first organic functional layer OF1 and may overlap one side of the first organic functional layer OF1. For example, as shown in FIG. 33, the first auxiliary electrode AE1 may extend in the second direction D2.

In an embodiment of the present invention, the first auxiliary electrode AE1 might not overlap the other side that is opposite to the one side of the first organic functional layer OF1. In other words, the first auxiliary electrode AE1 may be disposed on only one side of the first organic functional layer OF1.

In an embodiment of the present invention, as the first auxiliary electrode AE1 is patterned together with the first organic functional layer OF1, a boundary of the first auxiliary electrode AE1 may coincide with a boundary of the first organic functional layer OF1. For example, a side of the first auxiliary electrode AE1 may be coplanar with a side of the first organic functional layer OF1. In addition, the first auxiliary electrode AE1 might not overlap the central portion of the first organic functional layer OF1.

In an embodiment of the present invention, the first auxiliary electrode AE1 may be spaced apart from the inorganic capping layer ICL and the spacer SPC. In other words, the first auxiliary electrode AE1 might not contact the inorganic capping layer ICL and the spacer SPC.

In an embodiment of the present invention, the second auxiliary electrode AE2 may overlap the second organic functional layer OF2 and may overlap one side of the second organic functional layer OF2. For example, as shown in FIG. 33, the second auxiliary electrode AE2 may extend in the second direction D2.

In an embodiment of the present invention, the second auxiliary electrode AE2 might not overlap the other side opposite to the one side of the second organic functional layer OF2. In other words, the second auxiliary electrode AE2 may be disposed on only one side of the second organic functional layer OF2.

In an embodiment of the present invention, as the second auxiliary electrode AE2 is patterned together with the second organic functional layer OF2, a boundary of the second auxiliary electrode AE2 may coincide with a boundary of the second organic functional layer OF2. For example, a side of the second auxiliary electrode AE2 may be coplanar with a side of the second organic functional layer OF2. In addition, the second auxiliary electrode AE2 might not overlap the central portion of the second organic functional layer OF2.

In an embodiment of the present invention, the second auxiliary electrode AE2 may be spaced apart from the inorganic capping layer ICL and the spacer SPC. In other words, the second auxiliary electrode AE2 might not contact the inorganic capping layer ICL and the spacer SPC.

In an embodiment of the present invention, the third auxiliary electrode AE3 may overlap the third organic functional layer OF3 and may overlap one side of the third organic functional layer OF3. For example, as shown in FIG. 33, the third auxiliary electrode AE3 may extend in the second direction D2.

In an embodiment of the present invention, the third auxiliary electrode AE3 might not overlap the other side opposite to the one side of the third organic functional layer OF3. In other words, the third auxiliary electrode AE3 may be disposed on only one side of the third organic functional layer OF3.

In an embodiment of the present invention, as the third auxiliary electrode AE3 is patterned together with the third organic functional layer OF3, a boundary of the third auxiliary electrode AE3 may coincide with a boundary of the third organic functional layer OF3. For example, a side of the third auxiliary electrode AE3 may be coplanar with a side of the third organic functional layer OF3. In addition, the third auxiliary electrode AE3 might not overlap the central portion of the third organic functional layer OF3.

In an embodiment of the present invention, the third auxiliary electrode AE3 may be spaced apart from the inorganic capping layer ICL and the spacer SPC. In other words, the third auxiliary electrode AE3 might not contact the inorganic capping layer ICL and the spacer SPC.

The common electrode CE may be disposed on the first to third organic functional layers OF1, OF2, and OF3 and the above-described auxiliary electrodes AE1, AE2,and AE3. In an embodiment of the present invention, the common electrode CE may cover the first to third organic functional layers OF1, OF2, and OF3. In addition, the common electrode CE may cover the first auxiliary electrode AE1, the second auxiliary electrode AE2, and the third auxiliary electrode AE3.

In an embodiment of the present invention, the first auxiliary electrode AE1 may contact the common electrode CE. In other words, the first auxiliary electrode AE1 may be interposed between the first organic functional layer OF1 and the common electrode CE. In addition, the second auxiliary electrode AE2 may be interposed between the second organic functional layer OF2 and the common electrode CE, and the third auxiliary electrode AE3 may be interposed between the third organic functional layer OF3 and the common electrode CE.

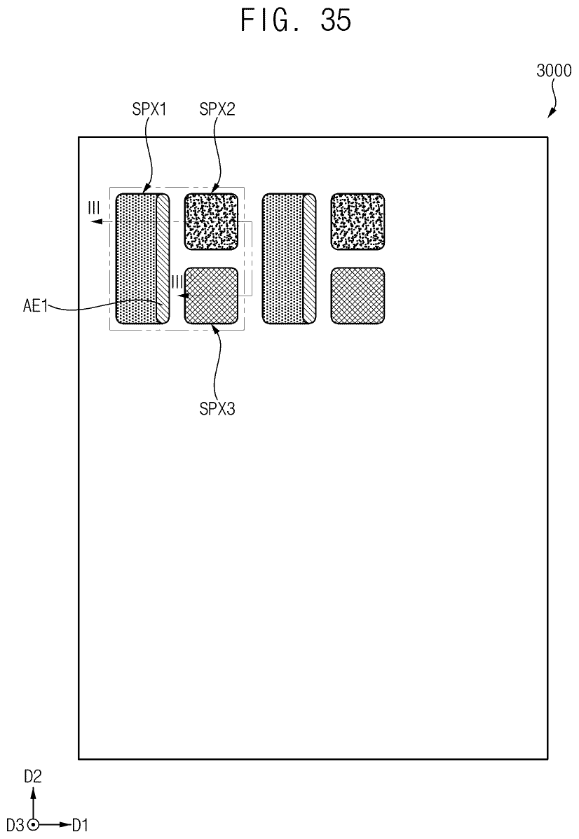

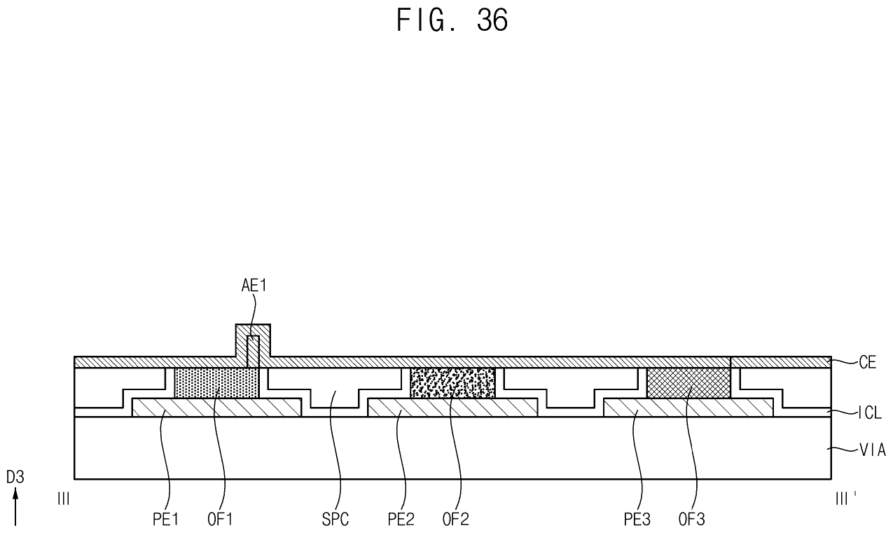

FIG. 35 is a plan view illustrating a display device according to an embodiment of the present invention. FIG. 36 is a cross-sectional view illustrating an emission layer included in the display device of FIG. 35. For example, FIG. 36 is a cross-sectional view taken along line III-III′ of FIG. 35.

Referring to FIG. 35, a display device 3000 according to an embodiment of the present invention may include a first auxiliary electrode AE1. However, the display device 3000 may be substantially the same as the display device 1000 described above, except for the first auxiliary electrode AE1.

In the display device 3000, the first auxiliary electrode AE1 may correspond to the first sub-pixel SPX1.

Referring to FIG. 36, the first auxiliary electrode AE1 may be disposed on the first organic functional layer OF1.

In an embodiment of the present invention, the first auxiliary electrode AE1 may overlap the first organic functional layer OF1 and may overlap one side of the first organic functional layer OF1. For example, as shown in FIG. 35, the first auxiliary electrode AE1 may extend in the second direction D2.

In an embodiment of the present invention, the first auxiliary electrode AE1 might not overlap the other side that is opposed to the one side of the first organic functional layer OF1. In other words, the first auxiliary electrode AE1 may be disposed on only one side of the first organic functional layer OF1.

In an embodiment of the present invention, as the first auxiliary electrode AE1 is patterned together with the first organic functional layer OF1, a boundary of the first auxiliary electrode AE1 may coincide with a boundary of the first organic functional layer OF1. For example, a side of the first auxiliary electrode AE1 may be coplanar with a side of the first organic functional layer OF1. In addition, the first auxiliary electrode AE1 might not overlap the central portion of the first organic functional layer OF1.

In an embodiment of the present invention, the first auxiliary electrode AE1 may be spaced apart from the inorganic capping layer ICL and the spacer SPC. In other words, the first auxiliary electrode AE1 might not contact the inorganic capping layer ICL and the spacer SPC.

The common electrode CE may be disposed on the first to third organic functional layers OF1, OF2, and OF3 and the first auxiliary electrode AE1. In an embodiment of the present invention, the common electrode CE may cover the first to third organic functional layers OF1, OF2, and OF3. In addition, the common electrode CE may cover the first auxiliary electrode AE1.

In an embodiment of the present invention, the first auxiliary electrode AE1 may further contact the common electrode CE. In other words, the first auxiliary electrode AE1 may be interposed between the first organic functional layer OF1 and the common electrode CE.

In an embodiment of the present invention, the common electrode CE may cover a whole surface of the second organic functional layer OF2. For example, the common electrode CE may contact the whole surface of the second organic functional layer OF2. In other words, any auxiliary electrode might not be formed on the second organic functional layer OF2.

In an embodiment of the present invention, the common electrode CE may cover a whole surface of the third organic functional layer OF3. For example, the common electrode CE may contact the whole surface of the third organic functional layer OF3. In other words, any auxiliary electrode might not be formed on the third organic functional layer OF3.

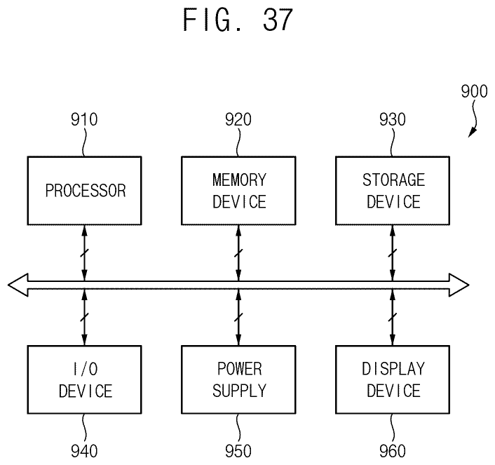

FIG. 37 is a block diagram illustrating an electronic device according to an embodiment of the present invention.

Referring to FIG. 37, in an embodiment, an electronic device 900 may include a processor 910, a memory device 920, a storage device 930, an input/output (“I/O”) device 940, a power supply 950, and a display device 960. Here, the display device 960 may correspond to the display device 1000 of FIG. 1, the display device 2000 of FIG. 33, and the display device 3000 of FIG. 35. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a first pixel electrode disposed on a substrate;
a first organic functional layer disposed on the first pixel electrode;
a first auxiliary electrode disposed on the first organic functional layer, and overlapping a first side of the first organic functional layer; and
a common electrode disposed on the first auxiliary electrode and covering the first organic functional layer and the first auxiliary electrode.

2. The display device of claim 1, wherein a boundary of the first auxiliary electrode is aligned with a boundary of the first organic functional layer.

3. The display device of claim 1, wherein the first auxiliary electrode does not overlap a central portion of the first organic functional layer.

4. The display device of claim 1, wherein the first auxiliary electrode contacts the common electrode.

5. The display device of claim 1, wherein the first auxiliary electrode is interposed between the first organic functional layer and the common electrode.

6. The display device of claim 1, wherein the first auxiliary electrode includes a same material as the common electrode.

7. The display device of claim 1, wherein the first auxiliary electrode includes a material that is different from a material of the common electrode.

8. The display device of claim 1, further comprising:
an inorganic capping layer disposed on the first organic functional layer and spaced apart from the first auxiliary electrode.

9. The display device of claim 8, further comprising:
a spacer disposed on the inorganic capping layer and spaced apart from the first auxiliary electrode.

10. The display device of claim 1, wherein the first auxiliary electrode includes:
a 1-1 auxiliary electrode overlapping the first side of the first organic functional layer; and
a 1-2 auxiliary electrode overlapping a second side that is opposite to the first side of the first organic functional layer.

11. The display device of claim 10, further comprising:
a second pixel electrode disposed on the substrate and spaced apart from the first pixel electrode;
a second organic functional layer disposed on the second pixel electrode;
a 2-1 auxiliary electrode disposed on the second organic functional layer, and overlapping a first side of the second organic functional layer; and
a 2-2 auxiliary electrode disposed on the second organic functional layer, and overlapping a second side opposite to the first side of the second organic functional layer.

12. The display device of claim 1, wherein the first auxiliary electrode does not overlap a second side that is opposite to the first side of the first organic functional layer.

13. The display device of claim 12, further comprising:
a second pixel electrode disposed on the substrate and spaced apart from the first pixel electrode;
a second organic functional layer disposed on the second pixel electrode; and
a second auxiliary electrode disposed on the second organic functional layer, and overlapping a first side of the second organic functional layer,
wherein the second auxiliary electrode does not overlap a second side that is opposite to the first side of the second organic functional layer.

14. The display device of claim 12, further comprising:
a second pixel electrode disposed on the substrate and spaced apart from the first pixel electrode; and
a second organic functional layer disposed on the second pixel electrode,
wherein the common electrode covers a whole surface of the second organic functional layer.

15. A method of manufacturing a display device, the method comprising:
forming a first pixel electrode on a substrate;
forming a first organic functional layer on the first pixel electrode;
forming a preliminary first auxiliary electrode layer on the first organic functional layer, wherein the preliminary first auxiliary electrode layer contacts the first organic functional layer;
forming a first auxiliary electrode by patterning the preliminary first auxiliary electrode layer, wherein the first auxiliary electrode overlaps a first side of the first organic functional layer; and
forming a common electrode on the first auxiliary electrode, wherein the common electrode covers the first organic functional layer and the first auxiliary electrode.

16. The method of claim 15, further comprising:
forming a preliminary inorganic capping layer on the preliminary first auxiliary electrode layer;
removing a portion of the preliminary inorganic capping layer that overlaps a central portion of the first organic functional layer, through a first etching process; and
forming a first auxiliary electrode layer by removing a portion of the preliminary first auxiliary electrode layer that overlaps the central portion of the first organic functional layer, through the first etching process.

17. The method of claim 16, further comprising:
removing a portion of the preliminary inorganic capping layer that overlaps the first side of the first organic functional layer, through a second etching process; and
forming a preliminary first auxiliary electrode by removing a portion of the first auxiliary electrode layer that overlaps the central portion of the first organic functional layer, through the second etching process.

18. The method of claim 17, wherein the first auxiliary electrode is formed by removing a portion of the preliminary first auxiliary electrode that overlaps the central portion of the first organic functional layer, through a third etching process.

19. The method of claim 15, further comprising:
forming a second pixel electrode on the substrate, wherein the second pixel electrode is spaced apart from the first pixel electrode;
depositing a first organic functional material layer covering the first pixel electrode and the second pixel electrode;
depositing a first auxiliary electrode material layer on the first organic functional material layer; and
forming the first organic functional layer and the preliminary first auxiliary electrode layer together, by patterning the first organic functional material layer and the first auxiliary electrode material layer.

20. The method of claim 19, further comprising:
depositing a second organic functional material layer on the first organic functional layer and the preliminary first auxiliary electrode layer;
depositing a second auxiliary electrode material layer on the second organic functional material layer; and
forming a second organic functional layer and a preliminary second auxiliary electrode layer together, by patterning the second organic functional material layer and the second auxiliary electrode material layer.

21. An electronic device comprising:
a display device; and
a power supply configured to provide power to the display device,
wherein the display device comprises:
a first pixel electrode disposed on a substrate;
a first organic functional layer disposed on the first pixel electrode;
a first auxiliary electrode disposed on the first organic functional layer, and overlapping a first side of the first organic functional layer; and
a common electrode disposed on the first auxiliary electrode and covering the first organic functional layer and the first auxiliary electrode.
